(19) United States
(12) Patent Application Publication
(10) Pub. No.: US 2006/0203867 A1
(43) Pub. Date: Sep. 14, 2006

(54) Laser diode chip, laser diode, and method for manufacturing laser diode chip

(75) Inventor: Yuji Imai, Hachiouji (JP)

Correspondence Address: BIRCH STEWART KOLASCH & BIRCH, PO BOX 747, FALLS CHURCH, VA, 22040-0747, US

(73) Assignees: Phenitec Semiconductor Corp.; Yuji IMAI

(21) Appl. No.: 11/244,363

(22) Filed: Oct. 6, 2005

(30) Foreign Application Priority Data
Mar. 8, 2005 (JP) 2005-64534
Mar. 8, 2005 (JP) 2005-64535
Mar. 8, 2005 (JP) 2005-64536
Mar. 8, 2005 (JP) 2005-64537

(51) Int. Cl. H01S 5/00

(52) U.S. Cl. 372/43.01

(57) ABSTRACT

Both lateral side portions of a laser diode chip separated by the central portions of a p-type capping layer and a p-type clad layer and parallel to the horizontal edges of the cleavage planes of the chip are cut away by etching, so that the p-type capping layer and the p-type clad layer take the shape of a mountain in cleavage planes which are the end faces of an active layer. The cut portions are provided with current restricting layers of oxide film made by baking a liquid oxide film. The thicknesses of the current restricting layers are increased with distance from the central portion of the laser diode chip.

### CROSS-REFERENCE TO RELATED APPLICATIONS

This Nonprovisional application claims priority under 35 U.S.C. §119(a) on Patent Applications Nos. 2005-64534, 2005-64535, 2005-64536, 2005-64537 filed in Japan on Mar. 8, 2005, the entire contents of which are hereby incorporated by reference.

### BACKGROUND OF THE INVENTION

The present invention relates to a laser diode chip, which is comprised of a semiconductor substrate and semiconductor layers and which outputs a laser beam, a laser diode provided with the laser diode chip, and a method for manufacturing the laser diode chip.

In recent days, optical disks are used to store data, such as audio data and image data, converted to digital signals. For example, with compact disks (CDs), laser diode provided with a laser diode chip, which outputs a laser beam with a wavelength of 780 nm (in the infrared region), is used for the writing and reading of data. Also, for example, with digital versatile disks (DVDs), a laser diode provided with a laser diode chip, which outputs a red laser beam with a wavelength of 650 nm in the visible region, is used for the writing and reading of data.

And further, through increased CD and DVD penetration, optical disk recording and reproducing apparatus and so on have a laser diode chip capable of outputting an infrared laser beam with a wavelength of 780 nm and a red laser beam with a wavelength of 650 nm so as to be able to handle both CDs and DVDs. Furthermore, as video and image processing technologies moves forward, there is a growing demand for an optical disk having a large storage capacity. For example, for next-generation large-capacity optical disks such as next-generation DVDs, the use of a laser diode which outputs a violet laser beam having a shorter wavelength is contemplated as a light source for recording and reproduction.

The laser diode chip which outputs the infrared laser beam has a structure in which an active layer of an AlGaAs-based semiconductor is sandwiched between a clad layer of a p-type AlGaAs-based semiconductor and a clad layer of a n-type AlGaAs-based semiconductor on a substrate of a n-type GaAs-based semiconductor, a n-type electrode is provided on the bottom surface of the n-type GaAs-based semiconductor substrate, and a p-type electrode is provide on the top surface of a p-type GaAs capping layer laminated on the p-type AlGaAs-based semiconductor clad layer. By applying a voltage between the electrodes to feed a current to the active layer, the laser beam with a wavelength of 780 nm is emitted from cleavage planes, that is, the end faces of the active layer, through the behavior of electrons and holes (carriers) which couple with each other in the active layer.

The laser diode chip which outputs the red laser beam has a structure in which an active layer of a GaInP-based semiconductor is sandwiched between a clad layer of a p-type AlGaInP-based semiconductor and a clad layer of a n-type AlGaInP-based semiconductor on a substrate of a n-type GaAs-based semiconductor, a n-type electrode is provided on the bottom surface of the n-type GaAs-based semiconductor substrate, and a p-type electrode is provided on the top surface of a p-type GaAs capping layer laminated on the p-type AlGaInP-based semiconductor clad layer. By applying a voltage between the electrodes to feed a current to the active layer, the laser beam with a wavelength of 650 nm is emitted from cleavage planes, that is, the end faces of the active layer, through the behavior of electrons and holes (carriers) which couple with each other in the active layer.

The laser diode chip which outputs the violet laser beam has a structure in which an active layer of a GaInN-based semiconductor is sandwiched between a clad layer of a p-type AlGaN-based semiconductor and a clad layer of a n-type AlGaN-based semiconductor on a substrate of a n-type GaN-based semiconductor, a n-type electrode is provided on the bottom surface of the n-type GaN-based semiconductor substrate, and a p-type electrode is provided on the top surface of a p-type GaN capping layer laminated on the p-type AlGaN-based clad layer. By applying a voltage between the electrodes to feed a current to the active layer, the laser beam with a wavelength of, for example, 405 nm is emitted from cleavage planes, that is, the end faces of the active layer, through the behavior of electrons and holes (carriers) which couple with each other in the active layer.

The laser diode chip which outputs laser beams with wavelengths of 780 nm and 650 nm has a semiconductor layer in which an active layer of an AlGaAs-based semiconductor is sandwiched between a clad layer of a p-type AlGaAs-based semiconductor and a clad layer of a n-type AlGaAs-based semiconductor on a substrate of a n-type GaAs-based semiconductor, a semiconductor layer in which an active layer of a GaInP-based semiconductor is sandwiched between a clad layer of a p-type AlGaInP-based semiconductor and a clad layer of a n-type AlGaInP-based semiconductor on the n-type GaAs-based semiconductor substrate, a n-type electrode provided on the bottom surface of the n-type GaAs-based semiconductor substrate, and p-type electrodes provided on the top surfaces of p-type GaAs capping layers laminated on the p-type AlGaAs-based semiconductor clad layer and the p-type AlGaInP-based semiconductor clad layer. By applying a voltage between the electrodes to feed a current to the active layers, laser beams with wavelengths of 780 nm and 650 nm are emitted from cleavage planes, that is, the end faces of the active layers, through the behavior of electrons and holes (carriers) which couple with each other in the active layers.

To generate lasing efficiently, there is a necessity to concentrate a current only into an active region which is a spatially restricted region in an active layer and to confine light generated by the coupling of electrons and holes in the active region. In terms of such a necessity, the structures of laser diode chips are broadly divided into two types, that is, a gain-guiding type structure and a refractive index-guiding type structure.

With the gain-guiding type structure, a change in resistance is caused at a clad layer of a p-type semiconductor (such as a clad layer of a p-type AlGaAs-based semiconductor, a clad layer of a p-type AlGaInP-based semiconductor, or a clad layer of a p-type AlGaN-based semiconductor) by, for example, ion implantation to form an insulating layer with a high electrical resistance, thereby a region into which a current is fed is restricted. When a voltage is applied between electrodes, a light gain is effected only in a region through which a current flows and the refractive index of the region is enhanced equivalently by the current; hence, the activated region comes to have the effect of a light guide, so that it becomes possible to confine the light. However, since the dimension of the active region is determined by the current flow and the active region expands due to the diffusion effect of the current and so on, the boundary of the active region fluctuates. Because of this, there are the disadvantages that a threshold current which starts laser oscillation is high and an astigmatic difference is large.

On the other hand, with the refractive index-guiding type structure, both lateral side portions of a clad layer of a p-type semiconductor (such as a clad layer of a p-type AlGaAs-based semiconductor, a clad layer of a p-type AlGaInP-based semiconductor, or a clad layer of a p-type AlGaN-based semiconductor) and an active layer (such as an active layer of an AlGaAs-based semiconductor, an active layer of a GaInP-based semiconductor, or an active layer of a GaInN-based semiconductor) which are vertical to the direction of their lamination are cut away longitudinally by etching, following which current restricting layers are formed onto both cut portions by growing semiconductor crystals through the use of epitaxial growth, thereby the active region is restricted. Since the active region is restricted physically, light is confined tightly, so that a threshold current lowers and an astigmatic difference becomes small when compared with that of the gain-guiding type structure.

FIGS. 1A to 1G are explanatory drawings of a process for manufacturing a laser diode chip which outputs an infrared, red, or violet laser beam by means of conventional crystal growth.

A wafer 200, which have been formed by growing some different crystals using epitaxial crystal growth so as to have a predetermined layer structure, is taken out of a crystal-growing furnace. An insulating film 201 is formed on the growth surface of the wafer 200 by P-CVD (chemical vapor deposition) (FIG. 1A). A photoresist 202 is applied onto the surface of the insulating film 201, exposure is conducted through the use of a mask, and exposed portions are removed with a chemical solution (FIG. 1B).

The insulating film 201 is removed by dry etching except for an unexposed portion (FIG. 1C). And then, both side portions of a clad layer are cut away by etching (FIG. 1D). The wafer 200, in which both side portions of the clad layer have been cut away, is placed into the crystal-growing furnace again and a semiconductor crystal 203 is grown in layer form (FIG. 1E). The semiconductor crystal 203 is removed by etching until the insulating film 201 is exposed (FIG. 1F), following which the exposed insulating film 201 is removed by etching (FIG. 1G). As a result, current restricting layers are formed which are made of the semiconductor crystal 203 different from the clad layer and the active layer in material.

FIGS. 2A to 2L are explanatory drawings of a process for manufacturing a laser diode chip which outputs infrared and red laser beams by means of conventional crystal growth.

A GaAs-based semiconductor layer 211 is formed on a n-type GaAs-based semiconductor substrate 210 by epitaxial crystal growth so as to have a predetermined layer structure (FIG. 2A). Part of the GaAs-based semiconductor layer 211 formed by the crystal growth is removed by etching until the substrate 210 is exposed (FIG. 2B). An insulating film 212 is formed on the surface of the GaAs-based semiconductor layer 211 (FIG. 2C), following which an AlGaInP-based/GaInP-based semiconductor layer 213 is formed onto the portion, from which the GaAs-based semiconductor layer 211 has been removed, by epitaxial crystal growth so as to have a predetermined layer structure (FIG. 2D). Thereafter the insulating film 212 is removed (FIG. 2E) to produce a wafer 220 used for the formation of two wavelengths.

An insulating film 221 is formed on the growth surface of the wafer 220 by P-CVD (FIG. 2F). A photoresist 222 is applied onto the surface of the insulating film 221, exposure is conducted through the use of a mask, and exposed portions are removed with a chemical solution (FIG. 2G). The insulating film 221 is removed by dry etching except for unexposed portions (FIG. 2H). And further, both side portions of the clad layers are cut away by etching (FIG. 2I). The wafer 220, in which both side portions of the clad layers have been cut away, is placed into the crystal-growing furnace again and a semiconductor crystal 223 is grown in layer form (FIG. 2J). The semiconductor crystal 223 is removed by etching until the insulating films 221 are exposed (FIG. 2K) and the exposed insulating films 221 are removed by etching (FIG. 2L). As a result, current restricting layers are formed which are made of the semiconductor crystals 223 different from the clad layer and the active layer in material.

However, in these conventional methods, there is a necessity to repeat the process of the crystal growth plural times to form the current restricting layers, which leads to a problem in that their production cost rises. In addition, the process of the crystal growth, which requires the precise control of layer thicknesses, often affects the yield of products, which leads to a problem in that the repetition of the process of the crystal growth results in the reduced yield of laser diode chips.

### BRIEF SUMMARY 0F-THE INVENTION

The present invention has been devised in view of such circumstances and hence, it is an object of the invention to provide a laser diode chip which outputs an infrared, red or violet laser beam, a laser diode provided with the laser diode chip, and a method for manufacturing the laser diode chip. The laser diode chip also offers other advantages not only in that a threshold current, by which laser oscillation is started, is decreased and an astigmatic difference is made small by providing current restricting layers, which have been formed by baking a liquid oxide film, so as to be opposite to each other with the central portion (stripe) of a clad layer of a p-type semiconductor, which lies substantially vertically to the direction of the lamination of the chip, interposed therebetween but in that the yield of the chip can be further improved than ever and the production cost of the chip can be reduced by eliminating the process of crystal growth twice through the provision of the current restricting layers.

Another object of the invention is to provide a laser diode chip, which is capable of confining light and carriers by increasing the thicknesses of current restricting layers with distance from the central portion (stripe) of a clad layer of a p-type semiconductor and which outputs an infrared, red, or violet laser beam, and a laser diode provided with the laser diode chip.

Still another object of the invention is to provide a laser diode chip, which has double heterostructures in the longitudinal and horizontal directions thereof by providing current restricting layers so as to be opposite to each other with the central portion (stripe) of a clad layer of a n-type semiconductor interposed between the layers and which outputs a high-efficiency infrared, red, or violet laser beam, and a laser diode provided with the laser diode chip.

Still another object of the invention is to provide a laser diode chip, which outputs a high-power infrared, red, or violet laser beam by using a multiple quantum well layer, in which quantum well layers and quantum barrier layers are laminated alternately, as an active layer, and a laser diode provided with the laser diode chip.

Still another object of the invention is to provide a laser diode chip, which outputs laser beams with two different wavelengths, a laser diode provided with the laser diode chip, and a method for manufacturing the laser diode chip. The laser diode chip also offers other advantages not only in that a threshold current, by which laser oscillation is started, is decreased and an astigmatic difference is made small by providing current restricting layers, which have been formed by baking a liquid oxide film, oppositely one after the other with the individual central portions (stripes) of a first p-type semiconductor clad layer and a second p-type semiconductor clad layer, which lie substantially vertically to the direction of the lamination of the chip, interposed therebetween but in that the yield of the chip is further improved than ever and the production cost of the chip is reduced by eliminating the process of crystal growth used for the formation of current restricting layers through the provision of such current restricting layers formed by baking the liquid oxide film.

Still another object of the invention is to provide a laser diode chip, which has an ability to confine light and carriers by increasing the thicknesses of current restricting layers with distance from the individual central portions (stripes) of the first and second p-type semiconductor clad layers and which outputs laser beams with two different wavelengths, and a laser diode provided with the laser diode chip.

Still another object of the invention is to provide a laser diode chip, which has double heterostructures in the longitudinal and horizontal directions thereof and which outputs high-efficient laser beams with two different wavelengths, and a laser diode provided with the laser diode chip. Such a structure is formed by providing current restricting layers so as to be opposite to each other with the central portions (stripes) of a first n-type semiconductor clad layer and a second n-type semiconductor clad layer interposed therebetween.

Still another object of the invention is to provide a laser diode chip, which is capable of outputting laser beams with wavelengths of 780 nm and 650 nm by providing an AlGaAs-based semiconductor layer and an AlGaInP-based semiconductor layer on a substrate, and a laser diode provided with the laser diode chip.

Still another object of the invention is to provide a laser diode chip, which outputs high-power laser beams with two different wavelengths by using a multiple quantum well layer comprising alternately laminated quantum well layers and quantum barrier layers as first and second active layers, and a laser diode provided with the laser diode chip.

A laser diode chip according to a first aspect of the invention has a structure in which at least a first clad layer of a n-type semiconductor, an active layer, and a second clad layer of a p-type semiconductor are laminated on a substrate in that order and in which current restricting layers formed by baking a liquid oxide film are provided so as to be opposite to each other with a central portion of the second clad layer, which lies substantially vertically to the direction of their lamination, interposed between the current restricting layers.

In the first aspect of the invention, the active region of the active layer is physically restricted by the current restricting layers formed by baking a liquid oxide film and light and carriers are confined in the active region. By providing the current restricting layers, which are formed by baking the liquid oxide film, so as to be opposite to each other with the central portion of the second clad layer sandwiched therebetween, that is, by providing the current restricting layers with the central portion of the second clad layer interposed therebetween, the current restricting layers, which physically restrict the active region of the active layer, can be provided instead of crystal growth, so that a threshold current, by which laser oscillation is started, can be decreased and an astigmatic difference can be made small.

When the cutaway portions of a clad layer has been thick, it has heretofore been impossible to provide current restricting layers by forming oxide film through, for example, vapor phase growth. However, according to the invention, since the liquid oxide film is used to provide the current restricting layers, it is possible to easily provide the current restricting layers irrespective of the shape of the cut surfaces of the clad layer cut away by etching and the depth or size of the cutaway portions. Therefore, current restricting layers having a desired structure can be formed, thereby any structure can be implemented easily in response to the desired characteristics of a laser diode.

A laser diode chip according to a second aspect of the invention has a structure in which the thicknesses of the current restricting layers described in the first aspect are increased with distance from the central portion of the second clad. In the second aspect, by increasing the thicknesses of the current restricting layers with distance from the central portion (stripe) of the second clad layer which lies substantially vertically to the direction of the lamination, it is possible to provide the current restricting layers with a refractive index equal to or lower than that of the clad layer to form a double heterostructure in the laser diode chip, thereby laser light and carriers can be confined.

A laser diode chip according to a third aspect of the invention has a structure in which the current restricting layers described in the first and second aspects are provided so as to be opposite to each other with a central portion of the first clad layer, which lies substantially vertically to the direction of the lamination, interposed therebetween. In the third aspect, the current restricting layers are provided so as to opposite to each other with the central portion (stripe) of the first clad layer of the n-type semiconductor interposed therebetween. Therefore the double heterostructures are formed in the longitudinal and horizontal directions of the laser diode chip, so that the carriers and light are confined in the active region more effectively, thereby the efficiency of light output is improved.

A laser diode chip according to a fourth aspect of the invention has a structure in which the active layer described in any one of the first to third aspects is a multiple quantum well layer alternately laminated with quantum well layers and quantum barrier layers. In the fourth aspect, the active layer is composed of the multiple quantum well layer alternately laminated with the quantum well layers and the quantum barrier layers both of which are extremely thin films at most 100 Å thick. As a result, the carriers confined in the active layer come to have a discrete energy level (sublevel) which is higher than their original energy level at an energy band. Since the transition of the carriers occurs between these sublevels, the energy of the light emission becomes high and the amplification of the light increases, thereby higher-efficiency laser oscillation is effected and a high-power laser beam is outputted.

A laser diode according to a fifth aspect of the invention has the laser diode chip described in any one of the first to fourth aspects. In the fifth aspect, by decreasing a threshold current by which laser oscillation is started, by making an astigmatic difference small, and by eliminating the process of crystal growth twice, the yield of the chip is further improved than ever and the production cost thereof is reduced. Also, since the laser light and the carriers can be confined, a high-power laser beam can be outputted.

A method for manufacturing of a laser diode chip according to a sixth aspect of the invention is a method for manufacturing a laser diode chip having a structure in which at least a first clad layer of a n-type semiconductor, an active layer, and a second clad layer of a p-type semiconductor are laminated on a substrate in that order which comprises the steps of forming an insulating film so as to cover a central portion of the second clad layer which lies substantially vertically to the direction of the lamination, removing part of the second clad layer uncovered with the insulating film by etching, applying an liquid oxide film onto the semiconductor layer and the insulating film each exposed by etching, baking the liquid oxide film applied, smoothening the baked oxide film by etching until the insulating film is exposed, and removing the exposed insulating film by etching.

In the sixth aspect, the insulating film is formed so as to cover the central portion (stripe) of the second clad layer of the p-type semiconductor. The part of the second clad layer uncovered with the insulating film is removed by etching. As a result, a spatial structure used for the provision of current restricting layers is formed. The liquid oxide film is applied onto the semiconductor layer and the insulating film each exposed by etching, and then the applied liquid oxide film is baked. As a consequence, the current restricting layers formed by baking the liquid oxide film are embedded with the central portion of the second clad layer interposed therebetween instead of crystal growth. The baked oxide film is smoothened by etching until the insulating film is exposed, and then the exposed insulating film is removed by etching. As a consequence, the current restricting layers made of the oxide film are formed with the central portion of the second clad layer interposed therebetween. The process of the crystal growth is eliminated twice, so that the yield of the laser diode chip can be further improved than ever and the production cost thereof can be reduced.

In the first to six aspects, the use of the first clad layer made of a n-type AlGaAs-based semiconductor, the active layer made of an AlGaAs-based semiconductor, and the second clad layer made of a p-type AlGaAs-based semiconductor leads to the implementation of a laser diode chip which outputs an infrared laser beam with a wavelength on the order of 780 nm, a laser diode provided with the laser diode chip, and a method for manufacturing the laser diode chip.

In the first to six aspects, the use of the first clad layer made of a n-type AlGaInP-based semiconductor, the active layer made of a GaInP-based semiconductor, and the second clad layer made of a p-type AlGaInP-based semiconductor leads to the implementation of a laser diode chip which outputs a red laser beam with a wavelength on the order of 650 nm, a laser diode provided with the laser diode chip, and a method for manufacturing the laser diode chip.

In the first to sixth aspects, the use of the first clad layer made of a n-type AlGaN-based semiconductor, the active layer made of a GaInN-based semiconductor, and the second clad layer made of a p-type AlGaInP-based semiconductor leads to the implementation of a laser diode chip which outputs a violet laser beam with a wavelength on the order of 405 nm, a laser diode provided with the laser diode chip, and a method for manufacturing the laser diode chip.

A laser diode chip according to a seventh aspect of the invention is a laser diode chip which outputs laser beams with different wavelengths by virtue of a structure in which at least a first n-type semiconductor clad layer, a first active layer, and a first p-type semiconductor clad layer are laminated on a substrate in that order, at least a second n-type semiconductor clad layer, a second active layer, and a second p-type semiconductor clad layer are laminated on the same substrate in that order, and current restricting layers formed by baking a liquid oxide film are provided oppositely one after the other with individual central portions of the first p-type semiconductor clad layer and the second p-type semiconductor layer, which lie substantially vertically to the directions of the laminations, interposed therebetween.

In the seventh aspect, both active regions of the first active layer and the second active layer are physically restricted by the current restricting layers formed by baking the liquid oxide film, and light and carriers are confined in the active regions. By providing the current restricting layers formed by baking the liquid oxide film oppositely one after the other with the individual central portions of the two p-type semiconductor clad layers interposed therebetween, the current restricting layers, which physically restrict the active regions of the active layers, can be provided instead of crystal growth, so that a threshold current, by which laser oscillation is started, can be decreased and an astigmatic difference can be made small.

When the cutaway portions of a clad layer have been thick, it has heretofore been impossible to provide current restricting layer by forming oxide film through, for example, vapor phase growth. However, in the seventh aspect, since the liquid oxide film is used to provide the current restricting layers, it is possible to easily provide the current restricting layers irrespective of the shape of the cut surfaces of the clad layer cut away by etching and the depth or size of the cutaway portions. Therefore, the current restricting layers can be formed so as to have a desired structure, thereby any structure can be implemented easily in response to the desired characteristics of a laser diode.

A laser diode chip according to an eighth aspect of the invention has a structure in which the thickness of the current restricting layers described in the seventh aspect is increased with distance from the individual central portions of the first and second p-type semiconductor clad layers. In the eight aspect, by increasing the thickness of the current restricting layers with distance from the individual central portions (stripes) of the first and second p-type semiconductor clad layers, it is possible to provide the current restricting layers with a refractive index equal to or lower than that of the clad layer to form a double heterostructure in the laser diode chip, thereby laser light and carriers can be confined.

A laser diode chip according to a ninth aspect of the invention has a structure in which the current restricting layers described in the seventh or eighth aspect are provided oppositely one after the other with the individual central portions of the first n-type semiconductor clad layer and the second n-type semiconductor clad layer, which lie substantially vertically to the direction of the lamination, interposed therebetween. In the ninth aspect, the current restricting layers are provided in the horizontal direction of the chip with the individual central portions (stripes) of the first n-type semiconductor clad layer and the second n-type semiconductor clad layer interposed therebetween. As a result, double heterostructures are formed in the longitudinal and horizontal directions of the laser diode chip, so that carriers and light are confined in the active region more efficiently, thereby the efficiency of light output can be improved.

A laser diode chip according to a tenth aspect of the invention has a structure in which the first and second active layers described in any one of the seventh to ninth aspects are multiple quantum well layers alternately laminated with quantum well layers and quantum barrier layers. In the tenth aspect, the first and second active layers are each the multiple quantum well layer alternately laminated with the quantum well layers and the quantum barrier layers both of which are made of extremely thin films at most 100 Å thick. As a consequence, the carriers confined in the active layers come to have a discrete energy level (sublevel) which is higher than their original energy level at an energy band. Since the transition of the carriers occurs between these sublevels, the energy of the light emission becomes high and the amplification of the light increases, thereby higher-efficiency laser oscillation can be effected and a high-power laser beam can be outputted.

A laser diode according to an eleventh aspect of the invention has the laser diode chip described in any one of the seventh to tenth aspects. In the eleventh aspect, a threshold current, by which laser oscillation is started, is decreased, an astigmatic difference is made small, and the process of crystal growth used for the provision of the current restricting layers is eliminated, thereby the yield of the chip is further improved than ever and the production cost thereof is reduced. Also, laser light and carriers can be confined and a high-power laser beam can be outputted.

A method for manufacturing a laser diode chip according to a twelfth aspect of the invention is a method for manufacturing a laser diode chip which outputs laser beams with different wavelengths by virtue of a structure in which at least a first n-type semiconductor clad layer, a first active layer, and a first p-type semiconductor clad are laminated on a substrate in that order and at least a second n-type semiconductor clad layer, a second active layer, and a second p-type semiconductor clad layer are laminated on the same substrate in that order. Such a manufacturing process comprises steps of forming insulating films so as to cover individual central portions of the first p-type semiconductor clad layer and the second p-type semiconductor clad layer which lie substantially vertically to the directions of the laminations, removing parts of the first and second p-type semiconductor clad layers uncovered with the insulating films by etching, applying a liquid oxide film onto the semiconductor layers and the insulating films each exposed by etching, baking the applied liquid oxide film, smoothening the baked oxide film by etching until the insulating films are exposed, and removing the exposed insulating films by etching.

In the twelfth aspect, the insulating films are formed so as to cover the individual central portions (stripes) of the first and second p-type semiconductor clad layers. The insulating film-uncovered parts of the first and second p-type semiconductor clad layers are removed by etching. As a consequence, spatial structures used for the provision of current restricting layers are formed. The liquid oxide film is applied onto the semiconductor layers and the insulating films each exposed by etching, and then the applied liquid oxide film is baked. As a result, instead of crystal growth, the current restricting layers formed by baking the liquid oxide film are embedded with the individual central portions of the first and second p-type semiconductor clad layers interposed therebetween. The baked oxide film is smoothened by etching until the insulating films are exposed, and then the exposed insulating films are removed by etching. As a consequence, the current restricting layers made of the oxide film are formed with the individual central portions of the first and second p-type semiconductor clad layers interposed therebetween. Therefore, the process of the crystal growth used for the provision of the current restricting layers is eliminated, so that the yield of the laser diode chip can be further improved than ever and the production cost thereof can be reduced.

In the seventh to twelfth aspects, when the first n-type semiconductor clad layer, the first active layer, and the first p-type semiconductor clad layer are AlGaAs-based semiconductors, when the second n-type semiconductor clad layer, and the second p-type semiconductor clad layers are AlGaInP-based semiconductors, and when the second active layer is GaInP-based semiconductor, the AlGaAs-based semiconductor layer and the AlGaInP-based semiconductor layer are provided on the substrate. In this case, a laser diode chip which outputs an infrared laser beam with a wavelength on the order of 780 nm and a red laser beam with a wavelength on the order of 650 nm, a laser diode provided with the laser diode chip, and a method for manufacturing the laser diode chip are implemented.

The above and further objects and features of the invention will more fully be apparent from the following detailed description with accompanying drawings.

### BRIEF DESCRIPTION OF THE SEVERAL VIEWS OF THE DRAWINGS

FIGS. 1A to 1G are explanatory drawings of a process for manufacturing a laser diode chip by means of conventional crystal growth;

FIGS. 2A to 2L are explanatory drawings of a process for manufacturing a laser diode chip by means of the conventional crystal growth;

FIG. 3 is a schematic diagram of the structure of a laser diode chip according to a first embodiment of the present invention;

FIGS. 4A to 4G are explanatory drawings of a process for manufacturing the laser diode chip according to the first embodiment of the invention;

FIGS. 5A and 5B are schematic diagrams of the structures of current restricting layers according to a second embodiment of the invention;

FIG. 6 is a schematic diagram of the structure of a high power-type laser diode chip according to a third embodiment of the invention;

FIG. 7 is a schematic diagram of the structure of a laser diode chip according to a fourth embodiment of the invention;

FIGS. 8A to 8G are explanatory drawings of a process for manufacturing the laser diode chip according to the fourth embodiment of the invention;

FIGS. 9A and 9B are schematic diagrams of the structures of current restricting layers according to a fifth embodiment of the invention;

FIG. 10 is a schematic diagram of the structure of a high power-type laser diode chip according to a sixth embodiment of the invention;

FIG. 11 is a schematic diagram of the structure of a laser diode chip according to a seventh embodiment of the invention;

FIGS. 12A to 12G are explanatory drawings of a process for manufacturing the laser diode chip according to the seventh embodiment of the invention;

FIGS. 13A and 13B are schematic diagrams of the structures of current restricting layers according to an eighth embodiment of the invention;

FIG. 14 is a schematic diagram of the structure of a high power-type laser diode chip according to a ninth embodiment of the invention;

FIG. 15 is a schematic diagram of the structure of a laser diode chip according to a tenth embodiment of the invention;

FIGS. 16A to 16L are explanatory drawings of a process for manufacturing the laser diode chip according to the tenth embodiment of the invention;

FIGS. 17A and 17B are schematic diagrams of the structures of current restricting layers according to an eleventh embodiment of the invention; and

FIG. 18 is a schematic diagram of the structure of a high power-type laser diode chip according to a twelfth embodiment of the invention.

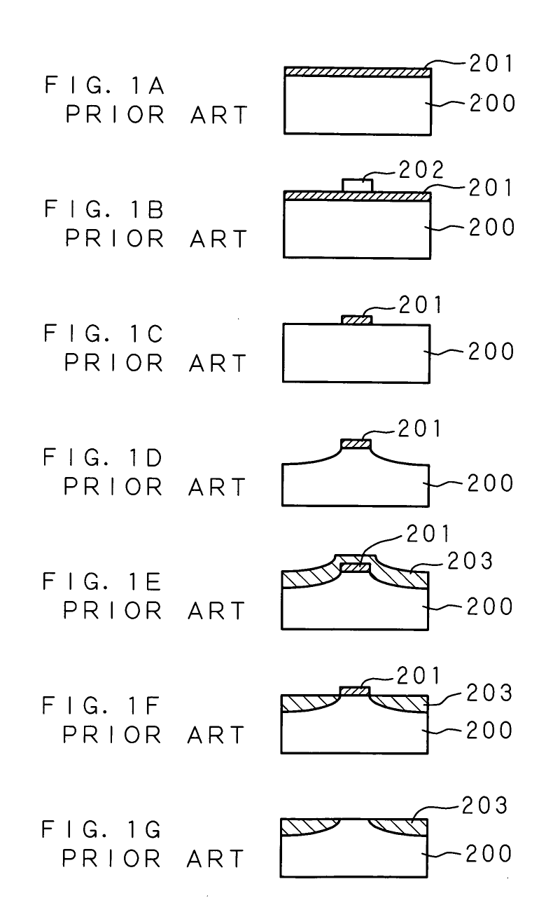

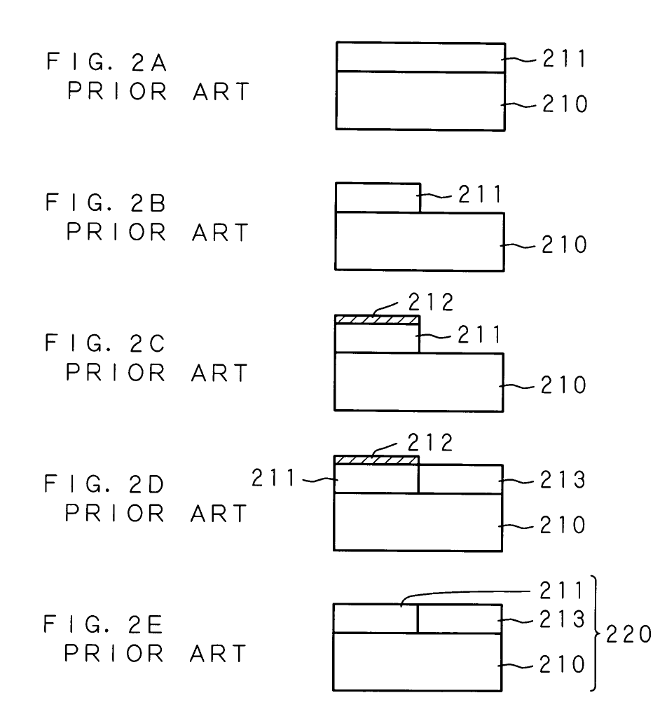

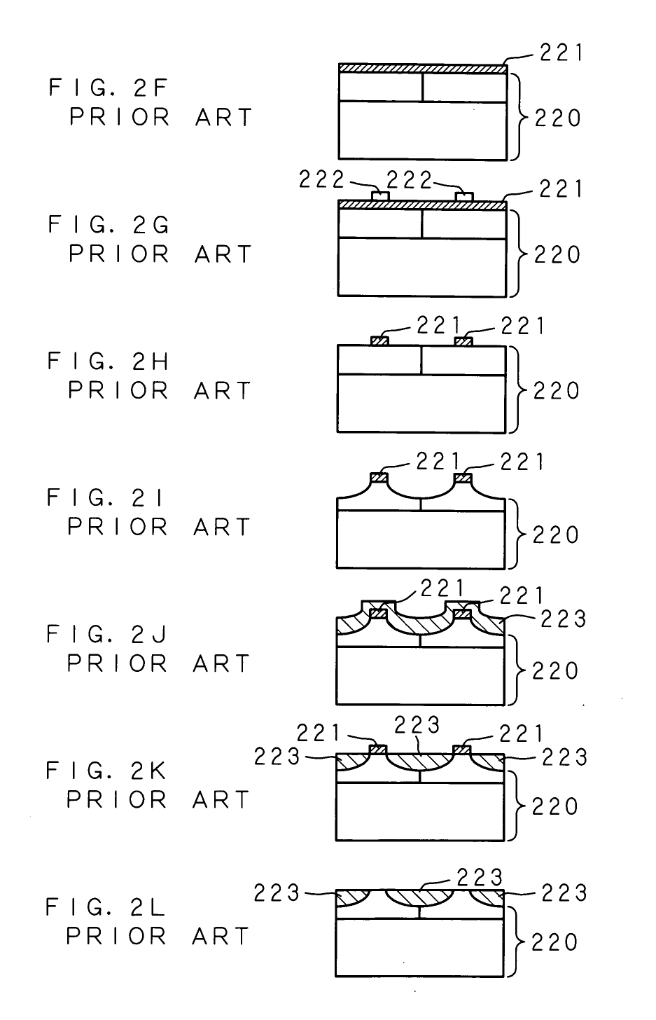

### DETAILED DESCRIPTION OF THE INVENTION

In the following, embodiments according to the present invention will be described in detail with reference to the drawings.

### First Embodiment

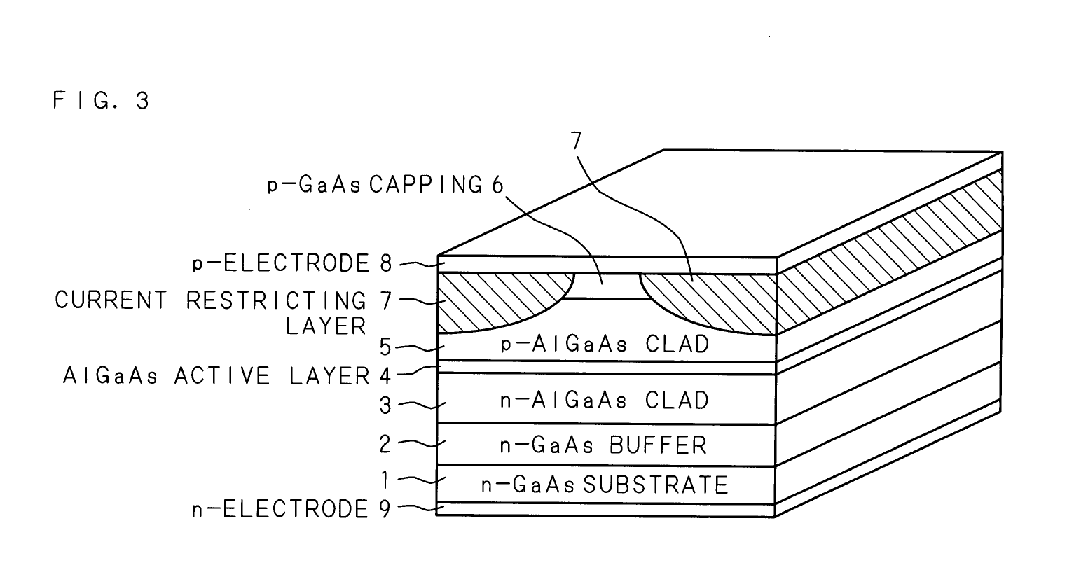

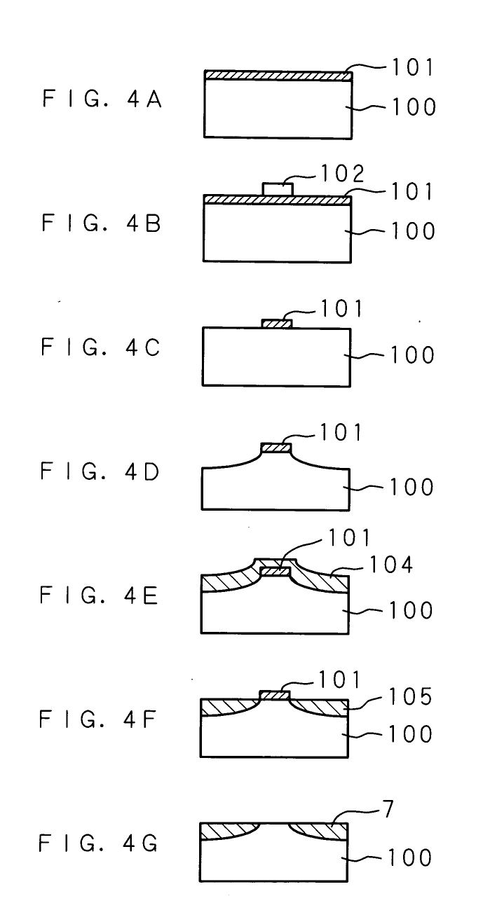

FIG. 3 is a schematic diagram of the structure of a laser diode chip according to a first embodiment of the invention. In FIG. 3, reference numeral 1 denotes a n-type GaAs substrate made of a n-type GaAs-based semiconductor crystal. The n-type GaAs substrate 1 is of the shape of, for example, a rectangular parallelepiped approximately 250 μm wide (width)×100 μm thick (height)×300 μm long.

On the n-type GaAs substrate 1, for example, an about 0.5 μm thick n-type GaAs buffer layer 2 made of n-type GaAs-based semiconductor crystal, an about 0.5 μm thick n-type AlGaAs clad layer 3 made of n-type AlGaAs-based semiconductor crystal, an about 0.06 μm thick AlGaAs active layer 4 made of AlGaAs-based semiconductor crystal, an about 0.5 μm thick p-type AlGaAs clad layer 5 made of p-type AlGaAs-based semiconductor crystal, and an about 0.5 μm thick p-type GaAs capping layer 6 made of p-type GaAs-based semiconductor crystal are laminated in that order by using epitaxial crystal growth. Note that the thicknesses of the individual layers are exaggerated to facilitate the understanding of the structure of the laser diode chip in FIG. 3 and the thicknesses of the layers other than the n-type GaAs substrate 1 are several μm or less.

Both lateral side portions separated by the central portions (stripes) of the p-type GaAs capping layer 6 and the p-type AlGaAs clad layer 5 and parallel to the horizontal edges of the cleavage planes of the laser diode chip are cut away by etching. The p-type GaAs capping layer 6 and the p-type AlGaAs clad layer 5 are of the shape of a mountain in the cleavage planes which are the end faces of the AlGaAs active layer 4. Current restricting layers 7, which are made of an oxide film formed by baking a liquid oxide film, are provided onto the cut portions. As a result, the current restricting layers 7 are provided so as to be opposite to each other with the central portions of the p-type GaAs capping layer 6 and the p-type AlGaAs clad layer 5, which lie vertically to the direction of the lamination, interposed therebetween. By providing the current restricting layers 7 whose refractive index is equal to or lower than those of the n-type AlGaAs clad layer 3 and the p-type AlGaAs clad layer 5, a double heterostructure is formed in the laser diode chip. A p-type electrode 8 is formed on the surfaces of the current restricting layers 7 and the p-type GaAs capping layer 6 and a n-type electrode 9 is formed on the bottom surface of the n-type GaAs substrate 1.

The laser diode chip is operated by feeding a forward current between the p-type electrode 8 and the n-type electrode 9. The current flowing into the AlGaAs active layer 4 via the p-type electrode 8 is restricted by the current restricting layers 7 and is confined in the restricted region (active region) of the AlGaAs active layer 4. Carriers (electrons and holes) injected by the current concentrate into the active region and light generated by the coupling of the carriers are confined in the active region by using the double heterostructure in which the AlGaAs active layer 4 having a high refractive index is sandwiched between the n-type AlGaAs clad layer 3 and the p-type AlGaAs clad layer 5 having low refractive indices. When the forward current is increased so as to exceed a threshold current, a laser oscillation occurs, thereby a laser beam with a wavelength of 780 nm can be taken out of the cleavage plane.

FIGS. 4A to 4G are explanatory drawings of a process for manufacturing the laser diode chip according to the first embodiment of the invention having the structure described above. A wafer 100, which has been made by laminating the n-type GaAs buffer layer, the n-type AlGaAs clad layer, the AlGaAs active layer, the p-type AlGaAs clad layer, and the p-type GaAs capping layer on the n-type GaAs substrate in that order by using epitaxial crystal growth, is taken out of a crystal-growing furnace, and then an insulating film 101 (for example, about 3 to 4 μm wide) is formed on the growth surface of the wafer 100 by using P-CVD (FIG. 4A). Thereafter, a photoresist 102 is applied onto the surface of the insulating film 101 and then exposure is conducted through the use of a mask, following which exposed portions are removed with a chemical solution (FIG. 4B).

The insulating film 101 other than unexposed portions is removed by dry etching (FIG. 4C). And further, both the side portions of the p-type GaAs capping layer and the p-type AlGaAs clad layer are cut away by etching with the central portions thereof left (FIG. 4D). Incidentally, the portions to be cut away can be cut away in gradually increasing their depth from the central portions to the longitudinal edges. To the wafer 100 having the p-type GaAs capping layer and the p-type AlGaAs clad layer whose both side portions have been cut away, a liquid oxide film 104 (for example, a coating liquid mainly comprising silicon oxide) is applied so as to have a desired thickness and to cover the insulating film 101, after which the wafer 100 is baked (for example, at temperatures of 80° C., 150° C., and 200° C. for about 1 minute each and then baked at a temperature of 400° C. to 500° C. for about 30 minutes) (FIG. 4E).

The baked oxide film 105 is removed by etching until the insulating film 101 is exposed, and then the surface of the oxide film 105 is smoothened (FIG. 4F), following which the exposed insulating film 101 is removed by etching (FIG. 4G). Therefore, instead of the growth of semiconductor crystal, the current restricting layers 7 are formed by baking the liquid oxide film 104.

A metal film serving as the p-type electrode 8 is formed on the surface of the wafer 100 in which the current restricting layers 7 are formed and a metal film serving as the n-type electrode 9 is formed on the bottom surface of the substrate 1. The wafer 100 having the metal films is cut into the individual laser diode chips. The two end faces (cleavage planes) of the diode chip, which serve as a light resonator, are made so as to be parallel to each other and to be flat. And finally, a laser diode is manufactured by mounting the laser diode chip onto a package and bonding a wire used for sending electric current.

As described above, by providing the current restricting layers, which are made of the liquid oxide film instead of conventional epitaxial crystal growth and which confine the carriers and light, with the central portions (stripes) of the p-type GaAs capping layer and the p-type AlGaAs clad layer sandwiched therebetween, the manufacture of the laser diode chip, which have heretofore involved the process of epitaxial crystal growth twice, can be conducted by involving the process of the epitaxial crystal growth only once; hence, it is possible to improve the yield of the chip resulting from the process of the epitaxial crystal growth, save time and labor required for the manufacturing process thereof, and reduce the production cost thereof. Also, through the physical provision of the current restricting layers to the p-type GaAs capping layer and the p-type AlGaAs clad layer, there are no disadvantages that a threshold current, by which laser oscillation is started, becomes large and an astigmatic difference is large.

In the first embodiment, the size of the substrate of the laser diode chip and the thicknesses of the individual semiconductor layers are merely examples and hence not limited to those numeric values. Also, it is needless to say that the proportions of the individual elements included in the AlGaAs-based semiconductor and the GaAs-based semiconductor can be set at desired numeric values.

### Second Embodiment

With the laser diode chip according to the first embodiment, both side portions of the p-type GaAs capping layer 6 are removed by etching, upper parts of both side portions of the p-type AlGaAs clad layer 5 are removed by etching, and then the current restricting layers 7 are provided to the cut portions; however, the structure of the current restricting layers 7 is not limited to such a structure.

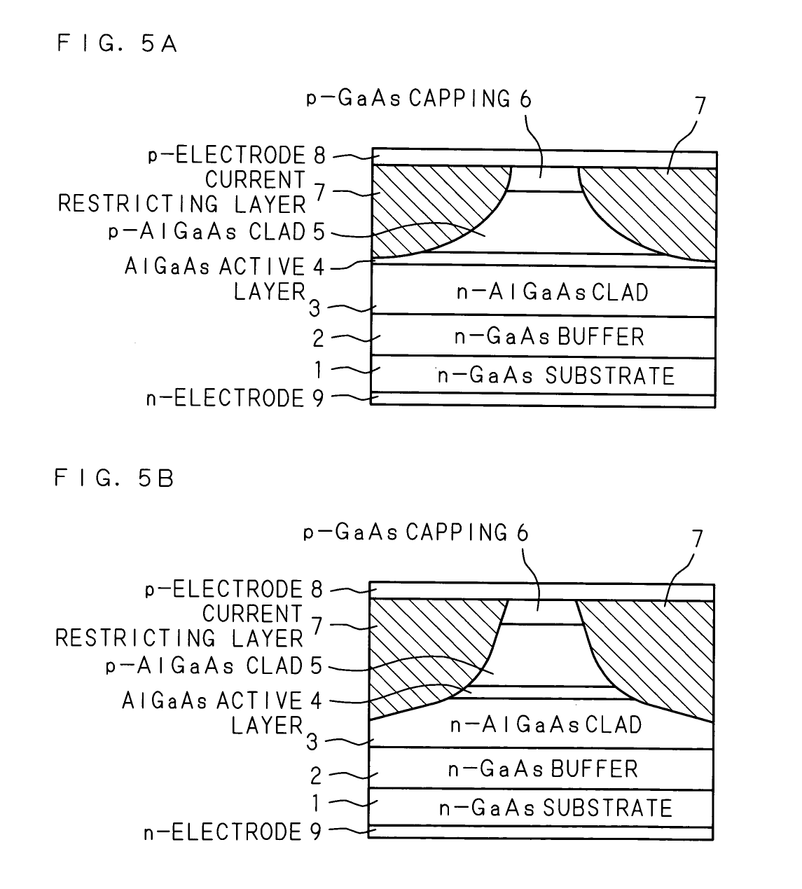

FIGS. 5A and 5B are schematic diagrams of the structures of current restricting layers 7. As shown in FIG. 5A, both side portions of the p-type GaAs capping layer 6 and the p-type AlGaAs clad layer 5 are removed by etching and upper parts of both side portions of the AlGaAs active layer 4 are removed by etching. The depths in the longitudinal direction of the removed portions are increased toward the longitudinal edges of the laser diode chip. The current restricting layers 7 formed by baking a liquid oxide film are provided to the cut portions.

Also, as shown in FIG. 5B, both side portions of the p-type GaAs capping layer 6, the p-type AlGaAs clad layer 5, and the AlGaAs active layer 4 are removed by etching and upper parts of both side portions of the n-type AlGaAs clad layer 3 are removed by etching. The depths in the longitudinal direction of the removed portions are increased toward the longitudinal edges of the laser diode chip. The current restricting layers 7 formed by baking a liquid oxide film are provided to the cut portions. Therefore, it is also possible to adopt a double heterostructure in both longitudinal and horizontal directions of the laser diode chip, thereby a higher-efficiency laser diode chip can be manufactured.

### Third Embodiment

The laser diode chips according to the first and second embodiments of the invention has a structure in which the active layer made of the AlGaAs-based semiconductor crystal is used and outputs the infrared laser beam with a laser beam power on the order of several mW to several tens of mW And further, it is also possible to apply such a structure to a laser diode chip which outputs an infrared laser beam with a high power on the order of a hundred mW to several hundreds of mW.

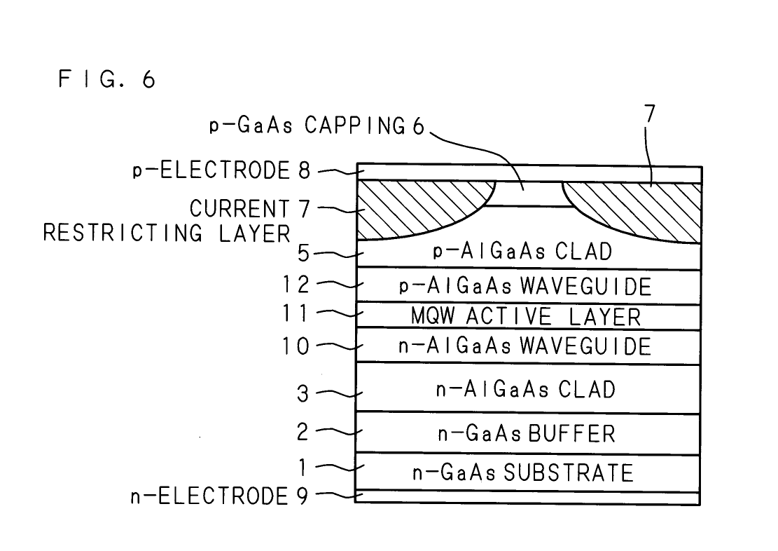

FIG. 6 is a schematic diagram of the structure of a high power-type laser diode chip. In FIG. 6, reference numeral 11 denotes an about 500 Å thick MQW (multi-quantum well) active layer made by alternately laminating quantum well layers, which are extremely thin films 100 Å thick or less and which are made of AlGaAs-based semiconductor crystal, and quantum barrier layers which are extremely thin films 100 Å thick or less and which are made of GaAs-based semiconductor crystal. A p-type AlGaAs waveguide layer 12, which is used to confine light and which is made of p-type AlGaAs-based semiconductor crystal, and a n-type AlGaAs waveguide layer 10, which is made of n-type AlGaAs-based semiconductor crystal, are provided so as to sandwich the MQW active layer 11. That is, the p-type AlGaAs waveguide layer 12 overlies the MQW active layer 11 and the n-type AlGaAs waveguide layer 10 underlies the MQW active layer 11. Incidentally, the explanation of the same components as those described in the first embodiment is omitted instead of giving the same reference numerals.

With the structure of the laser diode chip according to the third embodiment, both side portions of the p-type GaAs capping layer 6 are removed by etching, upper parts of both side portions of the p-type AlGaAs clad layer 5 are removed by etching, and the current restricting layers 7 are provided to the cut portions. The depths in the longitudinal direction of the current restricting layers 7 are increased toward the longitudinal edges of the laser diode chip.

As a result, carriers confined in the MQW active layer 11 come to have a discrete energy level (sublevel) higher than their energy level at an energy band. Since the transition of the carriers occurs between these sublevels, the energy of light emission is increased and the amplification of the light is increased. As a consequence, laser oscillation can be effected with small currents and a high-power laser beam can be outputted.

In the first, second, and third embodiment in which the laser diode chips which output the infrared laser beam having the wavelength on the order of 780 nm are described, the p-type AlGaAs clad layer 5 and the n-type AlGaAs clad layer 3 each have a single-layer structure, while their structures are not limited to such a single-layer structure; hence, plural p-type AlGaAs clad layers and n-type AlGaAs clad layers, which are made of semiconductor crystal having modified chemical compositions, may be provided.

### Fourth Embodiment

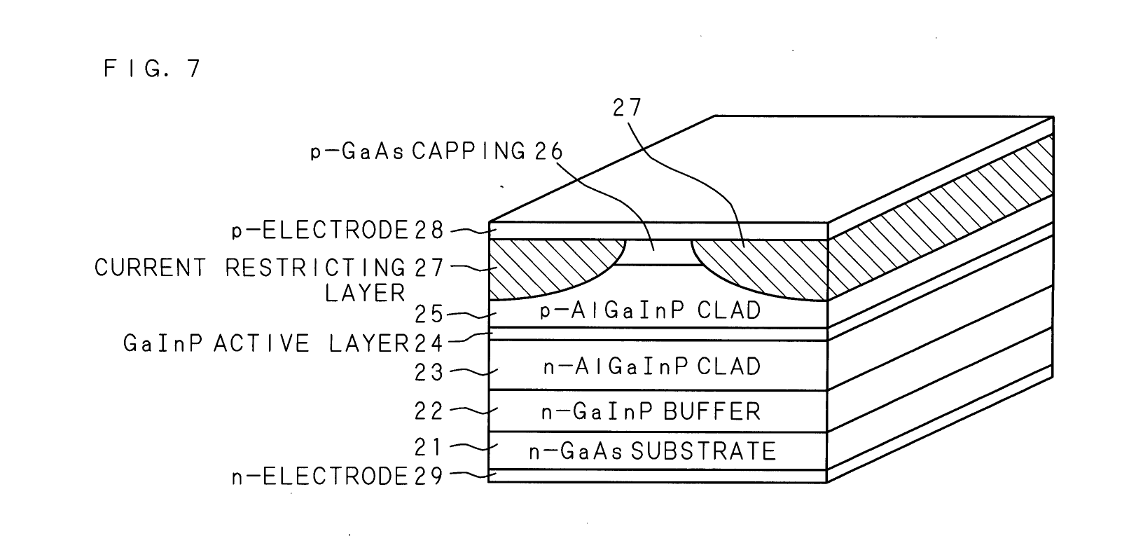

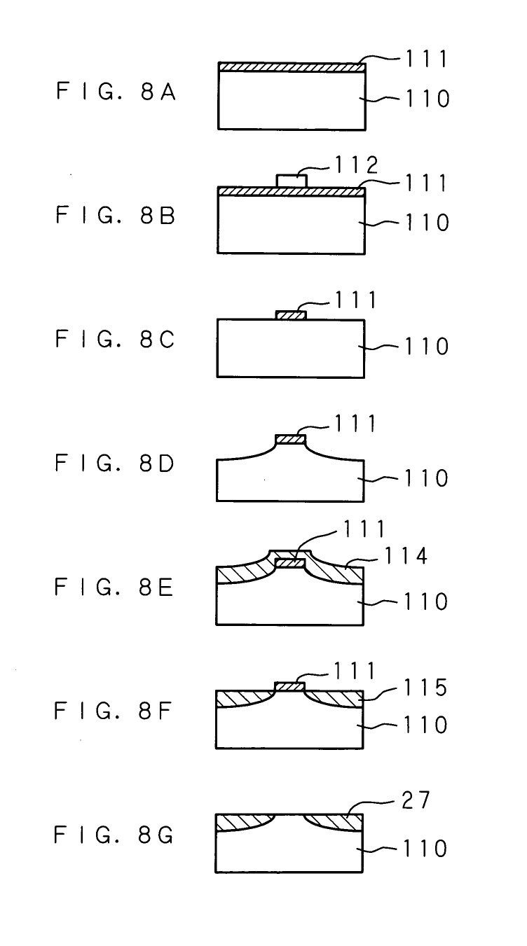

FIG. 7 is a schematic diagram of the structure of a laser diode chip according to a fourth embodiment of the invention. In FIG. 7, reference numeral 21 denotes a n-type GaAs substrate made of n-type GaAs-based semiconductor crystal. The n-type GaAs substrate 21 is of the shape of, for example, a rectangular parallelepiped approximately 250 μm wide (width)×100 μm thick (height)×300 μm long.

On the n-type GaAs substrate 21, for example, an about 0.5 μm thick n-type GaInP buffer layer 22 made of n-type GaInP-based semiconductor crystal, an about 0.5 μm thick n-type AlGaInP clad layer 23 made of n-type AlGaInP-based semiconductor crystal, an about 0.06 μm thick GaInP active layer 24 made of GaInP-based semiconductor crystal, an about 0.5 μm thick p-type AlGaInP clad layer 25 made of p-type AlGaInP-based semiconductor crystal, and an about 0.5 μm thick p-type GaAs capping layer 26 made of p-type GaAs-based semiconductor crystal are laminated in that order by epitaxial crystal growth. In FIG. 7, it is to be noted that the thicknesses of the individual layers are exaggerated to facilitate the understanding of the structure of the laser diode chip and the thicknesses of the layers other than the n-type GaAs substrate 21 are several μm or less.

Both lateral side portions, which are separated by the central portions (stripes) of the p-type GaAs capping layer 26 and the p-type AlGaInP clad layer 25 and which are parallel to the horizontal edges cleavage planes, are cut away by etching. The p-type GaAs capping layer 26 and the p-type AlGaInP clad layer are of the shape of a mountain in the cleavage planes, i.e., the end faces of the GaInP active layer 24. To the cut portions, current restricting layers 27, which are made of an oxide film formed by baking a liquid oxide film, are provided; hence, the two current restricting layers 27 are provided so as to be opposite to each other with the central portions of the p-type GaAs capping layer 26 and the p-type AlGaInP clad layer 25, which lie vertically to the direction of the lamination, interposed therebetween. That is, by providing the current restricting layers 27 whose refractive index is equal to or lower than that of the n-type AlGaInP clad layer 23, a double heterostructure is formed in the laser diode chip. A p-type electrode 28 is formed on the surfaces of the current restricting layers 27 and the p-type GaAs capping layer 26 and a n-type electrode 29 is formed on the bottom surface of the n-type GaAs substrate 21.

The laser diode chip is operated by feeding a forward current between the p-type electrode 28 and the n-type electrode 29. The current flowing into the GaInP active layer 24 via the p-type electrode 28 is restricted by the current restricting layers 27 and is confined in a restricted region (active region) in the GaInP active layer 24. Carriers (electrons and holes) injected by the current concentrate into the active region and light generated by the coupling of the carriers is confined in the active region by using the double heterostructure in which the GaInP active layer 24 with a high refractive index is sandwiched between the n-type AlGaInP clad layer 23 and the p-type AlGaInP clad layer 25 with low refractive indices. When the forward current is increased so as to exceed a threshold current, laser oscillation occurs, thereby a laser beam with a wavelength of 650 nm can be taken out of the cleavage plane.

FIGS. 8A to 8G are explanatory drawings of a process for manufacturing the laser diode chip according to the fourth embodiment of the invention having the structure described above. A wafer 110, which has been made by laminating the n-type GaInP buffer layer, the n-type AlGaInP clad layer, the GaInP active layer, the p-type AlGaInP clad layer, and the p-type GaAs capping layer on the n-type GaAs substrate in that order through epitaxial crystal growth, is taken out of a crystal-growing furnace, and then an insulating film 111 (for example, about 3 to 4 μm wide) is formed on the growth surface of the wafer 110 by using P-CVD (FIG. 8A). A photoresist 112 is applied onto the surface of the insulating film 111, and then exposure is conducted through the use of a mask, following which exposed portions are removed by using a chemical solution (FIG. 8B).

The insulating film 111 is removed by dry etching except for unexposed portions (FIG. 8C). And further, both side portions of the p-type GaAs capping layer and the p-type AlGaInP clad layer are cut away by etching with the central portions thereof left (FIG. 8D). Incidentally, the portions to be cut away can be cut away in gradually increasing their depths from the central portions to the longitudinal edges. To the wafer 110 having the p-type GaAs capping layer and the p-type AlGaInP clad layer whose both side portions have been cut away, a liquid oxide film 114 (for example, a coating liquid mainly comprising silicon oxide) is applied so as to have a desired thickness and to cover the insulating film 111, after which the wafer 110 is baked (for example, at temperatures of 80° C., 150° C., and 200° C. for about 1 minute each and then baked at a temperature of 400° C. to 500° C. for about 30 minutes) (FIG. 8E).

The baked oxide film 115 is removed by etching until the insulating film 111 is exposed, and then the surface of the oxide film 115 is smoothened (FIG. 8F), following which the exposed insulating film 111 is removed by etching (FIG. 8G). In this manner, the current restricting layers 27 are formed which are made by baking the liquid oxide film 114 instead of the growth of semiconductor crystal.

A metal film serving as the p-type electrode 28 is formed on the surface of the wafer 110 in which the current restricting layers 27 are formed and a metal film serving as the n-type electrode 29 is formed on the bottom surface of the substrate 21. The wafer 110 having the metal films is cut into the individual laser diode chips. The two end faces (cleavage planes) of the diode chip, which serve as a light resonator, are formed so as to be parallel to each other and to be flat. And finally, a laser diode is manufactured by mounting the laser diode chip onto a package and bonding a wire used for sending electric current.

As described above, by providing the current restricting layers, which are made of the liquid oxide film instead of conventional epitaxial crystal growth and which confine the carriers and light, with the central portions (stripes) of the p-type GaAs capping layer and the p-type AlGaInP clad layer interposed therebetween, the manufacture of the laser diode chip, which has heretofore involved the process of epitaxial crystal growth twice, can be done by using the process of the epitaxial crystal growth only once; hence, it is possible to improve the yield of the chip resulting from the process of the epitaxial crystal growth, save time and labor required for the manufacturing process thereof, and reduce the production cost thereof. Also, because of the physical provision of the current restricting layers to the p-type GaAs capping layer and the p-type AlGaInP clad layer, there are no disadvantages that the threshold current, by which the laser oscillation is started, becomes large and an astigmatic difference is large.

In the fourth embodiment, the size of the substrate of the laser diode chip and the thicknesses of the individual semiconductor layers are indicated as examples and hence not limited to those numeric values. Also, it is needless to say that the proportions of the individual elements included in the AlGaInP-based semiconductor and the GaInP-based semiconductor can be set at desired ratios.

### Fifth Embodiment

With the laser diode chip according to the fourth embodiment, both side portions of the p-type GaAs capping layer 26 are removed by etching, upper parts of both side portions of the p-type AlGaInP clad layer 25 are removed by etching, and then the current restricting layers 27 are provided to the cut portions; however, the structure of the current restricting layers 27 is not limited to such a structure.

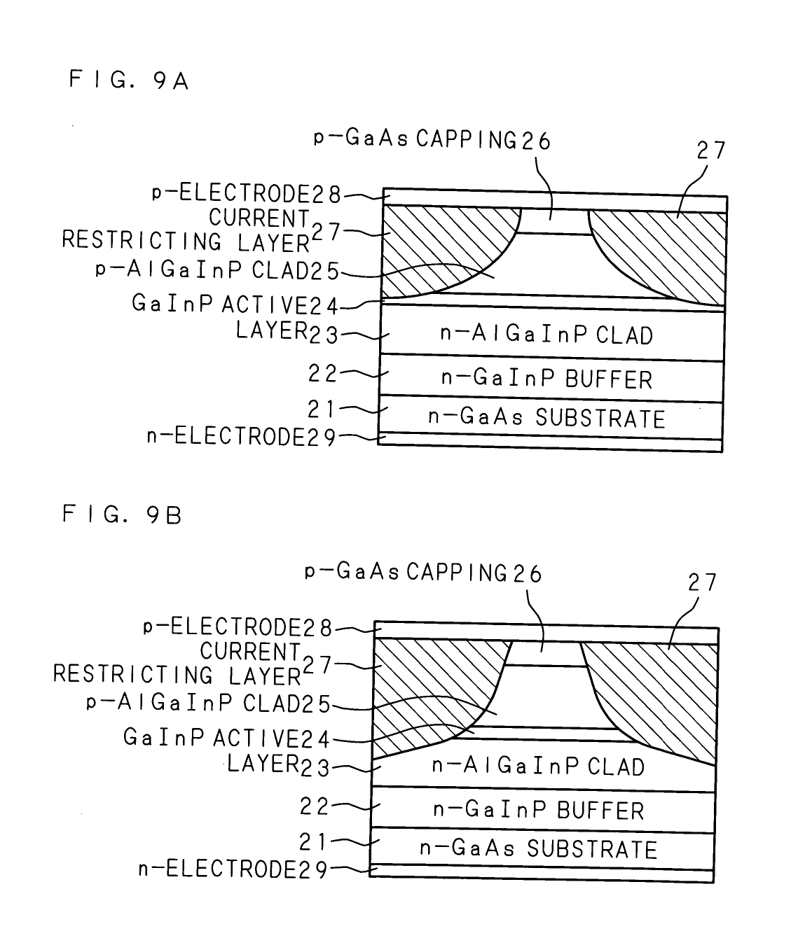

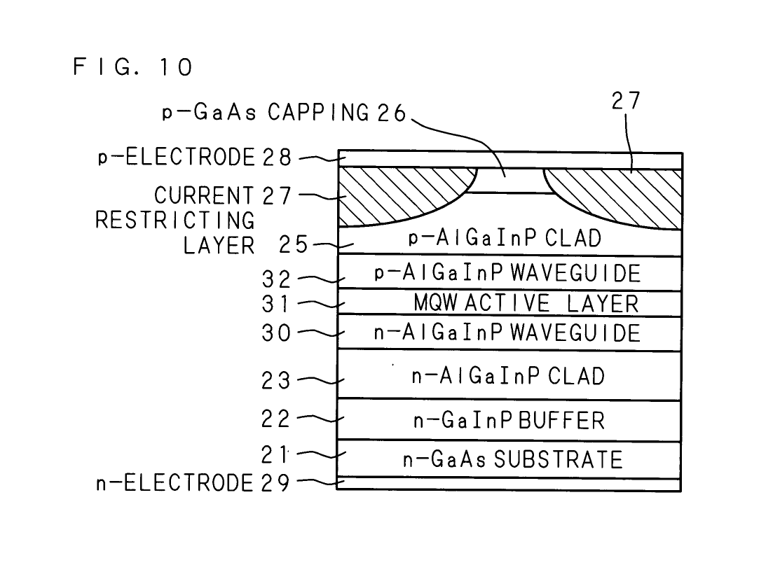

FIGS. 9A and 9B are schematic diagrams of the structures of the current restricting layers 27 according to the fifth embodiment of the invention. As shown in FIG. 9A, both side portions of the p-type GaAs capping layer 26 and the p-type AlGaInP clad layer 25 are removed by etching and upper parts of both side portions of the GaInP active layer 24 are removed by etching. The depths in the longitudinal direction of the removed portions are increased toward the longitudinal edges of the laser diode chip. The current restricting layers 27 formed by baking a liquid oxide film are provided to the cut portions.

Also, as shown in FIG. 9B, both side portions of the p-type GaAs capping layer 26, the p-type AlGaInP clad layer 25, and the GaInP active layer 24 are removed by etching and upper parts of both side portions of the n-type AlGaInP clad layer 23 are removed by etching. The depths of the removed portions are increased toward the longitudinal edges of the laser diode chip. The current restricting layers 27 formed by baking a liquid oxide film are provided to the cut portions. Therefore, it is also possible to adopt a double heterostructure in longitudinal and horizontal directions of the laser diode chip, thereby a higher-efficiency laser diode chip can be manufactured.

### Sixth Embodiment

The laser diode chips according to the fourth and fifth embodiments of the invention have the structures in which the active layer made of the GaInP-based semiconductor crystal is used and output the red laser beam with a laser power on the order of several mW to several tens of mW And further, it is also possible to apply such a structure to a laser diode chip which outputs a red laser beam with a high power on the order of a hundred mW to several hundreds of mW.

FIG. 10 is a schematic diagram of the structure of a high power-type laser diode chip. In FIG. 10, reference numeral 31 denotes an about 500 Å thick MQW active layer made by alternately laminating quantum well layers, which are an extremely thin film 100 Å thick or less and which are made of GaInP-based semiconductor crystal, and quantum barrier layers which are an extremely thin film 100 Å thick or less and which are made of AlGaInP-based semiconductor crystal. A p-type AlGaInP waveguide layer 32, which is used to confine light and which is made of p-type AlGaInP-based semiconductor crystal, and a n-type AlGaInP waveguide layer 30, which is made of n-type AlGaInP-based semiconductor crystal, are provided so as to sandwich the MQW active layer 31; that is, the p-type AlGaInP waveguide layer 32 overlies the MQW active layer 31 and the n-type AlGaInP waveguide layer 30 underlies the MQW active layer 31. Incidentally, the explanation of the same components as those described in the fourth embodiment is omitted instead of giving the same reference numerals.

With the structure of the laser diode chip according to the sixth embodiment, both side portions of the p-type GaAs capping layer 26 are removed by etching, upper parts of both side portions of the p-type AlGaInP clad layer 25 are removed by etching, and the current restricting layers 27 are provided to the cut portions. The depths of the current restricting layers 27 are increased toward the longitudinal edges of the laser diode chip.

As a result, carriers confined in the MQW active layer 31 come to have a discrete energy level (sublevel) higher than their energy level at an energy band. Since the transition of the carriers occurs between these sublevels, the energy of light emission is increased and the amplification of the light is increased. As a consequence, laser oscillation can be effected with small currents and a high-power laser beam can be outputted.

In the fourth, fifth, and sixth embodiments of the invention in which the laser diode chips which output the red laser beam with the wavelength on the order of 650 nm are described, the p-type AlGaInP clad layer 25 and the n-type AlGaInP clad layer 23 each have a single-layer structure; however, their structures are not limited to such a structure and hence, plural p-type AlGaInP clad layers and n-type AlGaInP clad layers may be provided both of which are made of semiconductor crystal having modified chemical compositions.

### Seventh Embodiment

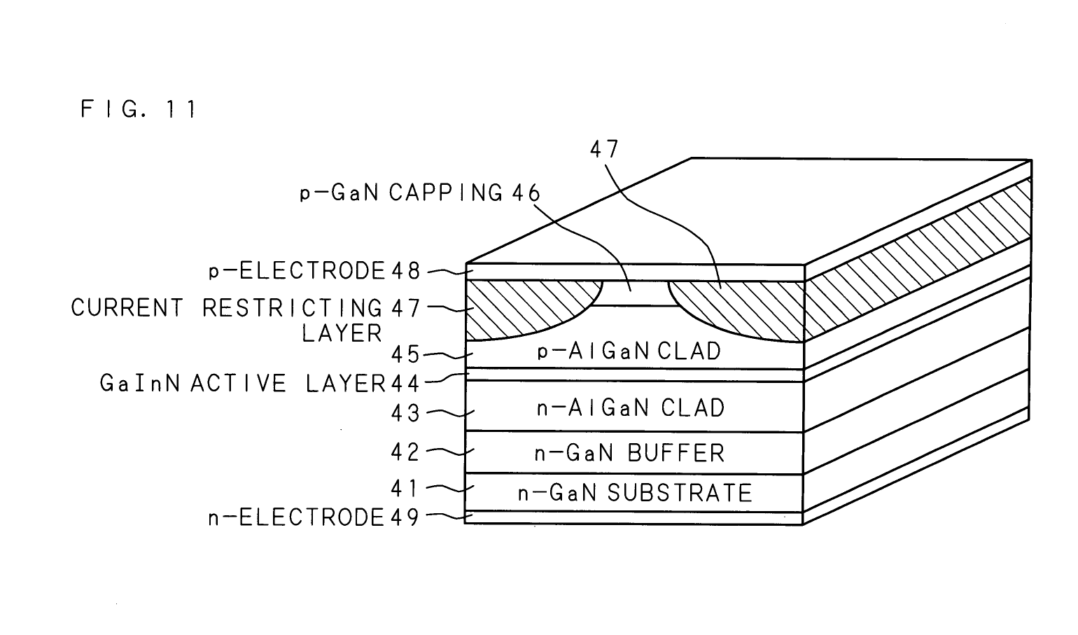

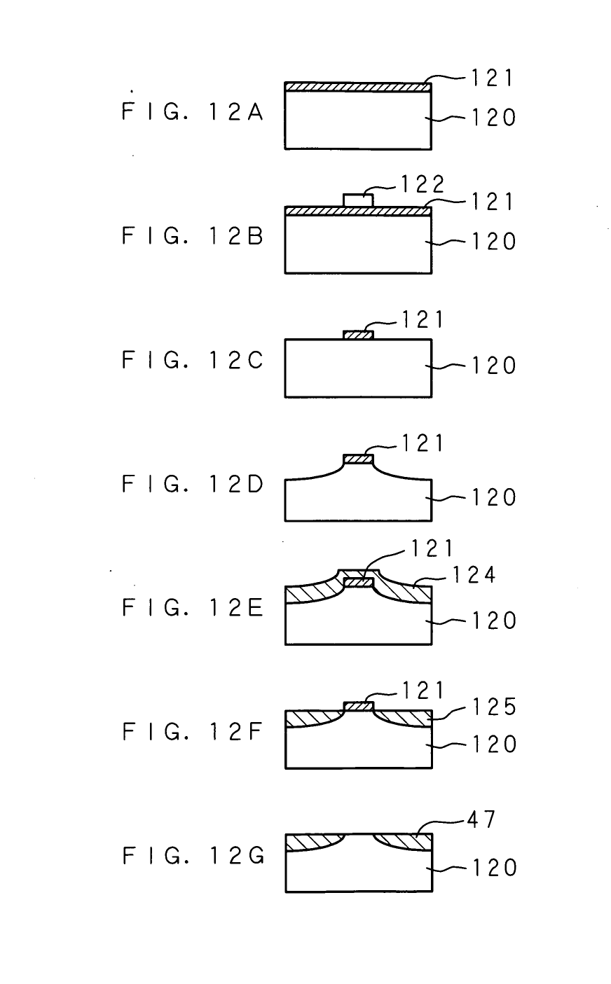

FIG. 11 is a schematic diagram of the structure of laser diode chip according to a seventh embodiment of the invention. In FIG. 11, reference numeral 41 denotes a n-type GaN substrate made of n-type GaN-based semiconductor crystal. The n-type GaN substrate 41 is of the shape of, for example, a rectangular parallelepiped approximately 250 μm wide (width)×100 μm thick (height)×300 μm long.

On the n-type GaN substrate 41, for example, an about 0.5 μm thick n-type GaN buffer layer 42 made of n-type GaN-base semiconductor crystal, an about 0.5 μm thick n-type AlGaN clad layer 43 made of n-type AlGaN-based semiconductor crystal, an about 0.1 μm thick GaInN active layer 44 made of GaInN-based semiconductor crystals, an about 0.5 μm thick p-type AlGaN clad layer 45 made of p-type AlGaN-based semiconductor crystal, and an about 0.5 μm thick p-type GaN capping layer 46 of p-type GaN-based semiconductor crystal are laminated in that order by epitaxial crystal growth. In FIG. 11, it should be noted that the thicknesses of the individual layers are exaggerated to facilitate the understanding of the structure of the laser diode chip and the thicknesses of the layers other than the n-type GaN substrate 41 are several μm or less.

Both side portions, which are separated by the central portions of the p-type GaN capping layer 46 and the p-type AlGaN clad layer 45 and which are parallel to cleavage planes, are cut away by etching. The p-type GaN capping layer 46 and the p-type AlGaN clad layer 45 are of the shape of a mountain in cleavage planes which are the end faces of the GaInN active layer 44. To the cut portions, current restricting layers 47, which are made of an oxide film formed by baking a liquid oxide film, are provided; hence, the two current restricting layers 47 are provided so as to be opposite to each other with the central portions of the p-type GaN capping layer 46 and the p-type AlGaN clad layer 45, which lie vertically to the direction of the lamination, interposed therebetween. That is, by providing the current restricting layers 47 whose refractive index is equal to or lower than that of the n-type AlGaN clad layer 43, a double heterostructure is formed in the laser diode chip. A p-type electrode 48 is formed on the surfaces of the current restricting layers 47 and the p-type GaN capping layer 46 and a n-type electrode 49 is formed on the bottom surface of the n-type GaN substrate 41.

The laser diode chip is operated by feeding a forward current between the p-type electrode 48 and the n-type electrode 49. The current flowing into the GaInN active layer 44 via the p-type electrode 48 is restricted by the current restricting layers 47 and is confined in a restricted region (active region) in the GaInN active layer 44. Carriers (electrons and holes) injected by the current concentrate into the active region and light generated by the coupling of the carriers is confined in the active region by using the double heterostructure in which the GaInN active layer 44 with a high refractive index is sandwiched between the n-type AlGaN clad layer 43 and the p-type AlGaN clad layer 45 with low refractive indices. When the forward current is increased so as to exceed a threshold current, laser oscillation occurs, thereby, for example, a laser beam with a wavelength of 405 nm can be taken out of the cleavage plane.

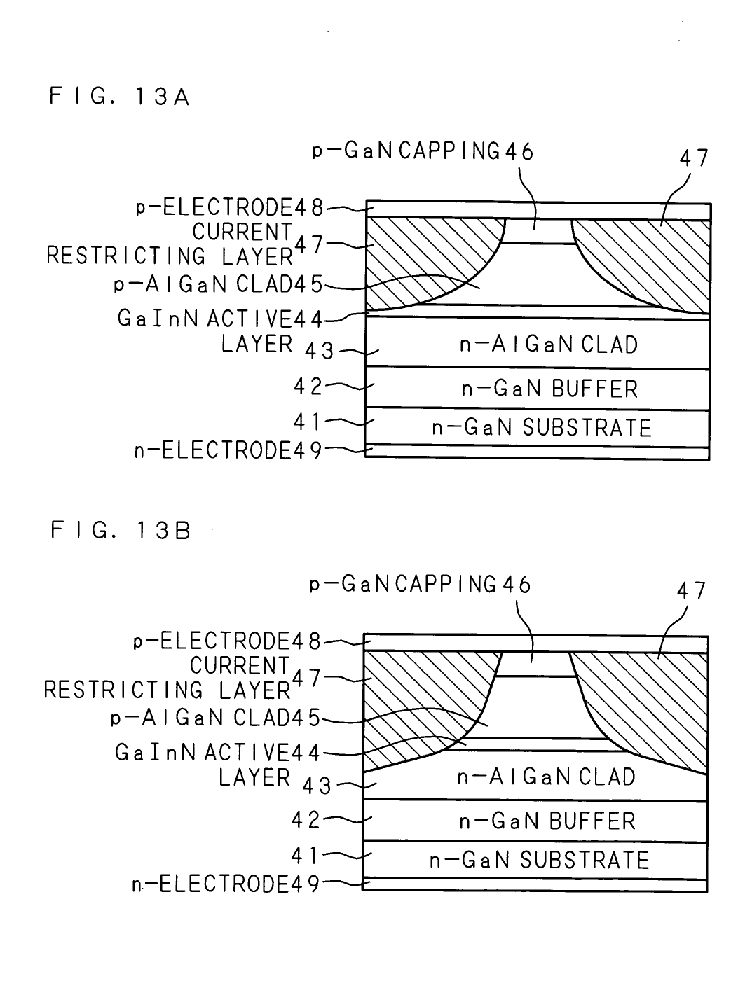

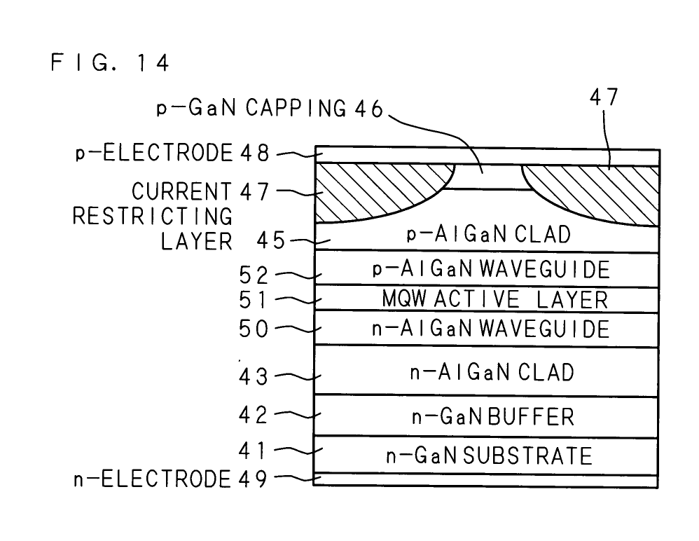

FIGS. 12A to 12G are explanatory drawings of a process for manufacturing the laser diode chip according to the seventh embodiment of the invention having the structure described above. A wafer 120, which has been made by laminating the n-type GaN buffer layer, the n-type AlGaN clad layer, the GaInN active layer, the p-type AlGaN clad layer, and the p-type GaN capping layer on the n-type GaN substrate in that order through epitaxial crystal growth, is taken out of a crystal-growing furnace, and then an insulating film 121 (for example, about 3 to 4 μm wide) is formed on the growth surface of the wafer 120 by using P-CVD (FIG. 12A). A photoresist 122 is applied onto the surface of the insulating film 121, and then exposure is conducted through the use of a mask, following which exposed portions are removed by using a chemical solution (FIG. 12B).

The insulating film 121 is removed by dry etching except for unexposed portions (FIG. 12C). And further, both side portions of the p-type GaN capping layer and the p-type AlGaN clad layer are cut away by etching with the central portions thereof left (FIG. 12D). Incidentally, the portions to be cut away can be cut away in gradually increasing their depths from the central portions to the longitudinal edges. To the wafer 120 having the p-type GaN capping layer and the p-type AlGaN clad layer whose both side portions have been cut away, a liquid oxide film 124 (for example, a coating liquid mainly comprising silicon oxide) is applied so as to have a desired thickness and to cover the insulating film 121, after which the wafer 120 is baked (for example, at temperatures of 80° C., 150° C., and 200° C. for about 1 minute each and then backed at a temperatures of 400° C. to 500° C. for about 30 minutes) (FIG. 12E).

The baked oxide film 125 is removed by etching until the insulating film 121 is exposed, and then the surface of the oxide film 125 is smoothened (FIG. 12F), following which the exposed insulating film 121 is removed by etching (FIG. 12G). In this manner, the current restricting layers 47 are formed which are made by baking the liquid oxide film 124 instead of the growth of semiconductor crystal.

A metal film serving as the p-type electrode 48 is formed on the surface of the wafer 120 in which the current restricting layers 47 are formed and a metal film serving as the n-type electrode 49 is formed on the bottom surface of the substrate 41. The wafer 120 having the metal films is cut into the individual laser diode chips. The two end faces (cleavage planes) of the diode chip, which serve as a light resonator, are formed so as to be parallel to each other and to be flat. And finally, a laser diode is manufactured by mounting the laser diode chip onto a package and bonding a wire used for sending electric current.

As described above, by providing the current restricting layers, which are made of the liquid oxide film instead of conventional epitaxial crystal growth and which confine the carriers and light, with the central portions (stripes) of the p-type GaN capping layer and the p-type AlGaN clad layer sandwiched therebetween, the manufacture of the laser diode chip, which has heretofore involved the process of epitaxial crystal growth twice, can be done by using the process of the epitaxial crystal growth only once; hence, it is possible to improve the yield of the chip resulting from the process of the epitaxial crystal growth, save time and labor required for the manufacturing process thereof, and reduce the production cost thereof. Also, through the physical provision of the current restricting layers to the p-type GaN capping layer and the p-type AlGaN clad layer, there are no disadvantages that the threshold current, by which the laser oscillation is started, becomes large and an astigmatic difference is large.

In the seventh embodiment, the size of the substrate of the laser diode chip and the thicknesses of the individual semiconductor layers are indicated as examples and hence are not limited to those numeric values. Also, it is needless to say that the proportions of the individual elements included in the AlGaN-based semiconductor and the GaInN-based semiconductor can be set at desired ratios.

### Eighth Embodiment

With the laser diode chip according to the seventh embodiment of the invention, both side portions of the p-type GaN capping layer 46 are removed by etching, upper parts of both side portions of the p-type AlGaN clad layer 45 are removed by etching, and then the current restricting layers 47 are provided to the cut portions; however the structure of the current restricting layers 47 is not limited to such a structure.

FIGS. 13A and 13B are schematic diagrams of the structures of the current restricting layers 47 according to the eighth embodiment of the invention. As shown in FIG. 13A, both side portions of the p-type GaN capping layer 46 and the p-type AlGaN clad layer 45 are removed by etching and upper parts of both side portions of the GaInN active layer 44 are removed by etching. The depths in the longitudinal direction of the removed portions are increased toward the longitudinal edges of the laser diode chip. The current restricting layers 47 formed by baking a liquid oxide film are provided to the removed portions.

Also, as shown in FIG. 13B, both side portions of the p-type GaN capping layer 46, the p-type AlGaN clad layer 45, and the GaInN active layer 44 are removed by etching and upper parts of both side portions of the n-type AlGaN clad layer 43 are removed by etching. The depths of the removed portions are increased toward the longitudinal edges of the laser diode chip. The current restricting layers 47 formed by baking a liquid oxide film are provided to the cut portions. Therefore, it is also possible to adopt the double heterostructure in the longitudinal and horizontal directions of the laser diode chip, thereby a higher-efficiency laser diode chip can be manufactured.

### Ninth Embodiment

The laser diode chips according to the seventh and eighth embodiments of the invention have such structures, in which the active layer made of the GaInN-based semiconductor crystal is used, and output the violet laser beam with the laser power on the order of several mW to a ten and several mW. And further, it is also possible to apply such structures to a laser diode chip which outputs a higher-power violet laser beam.

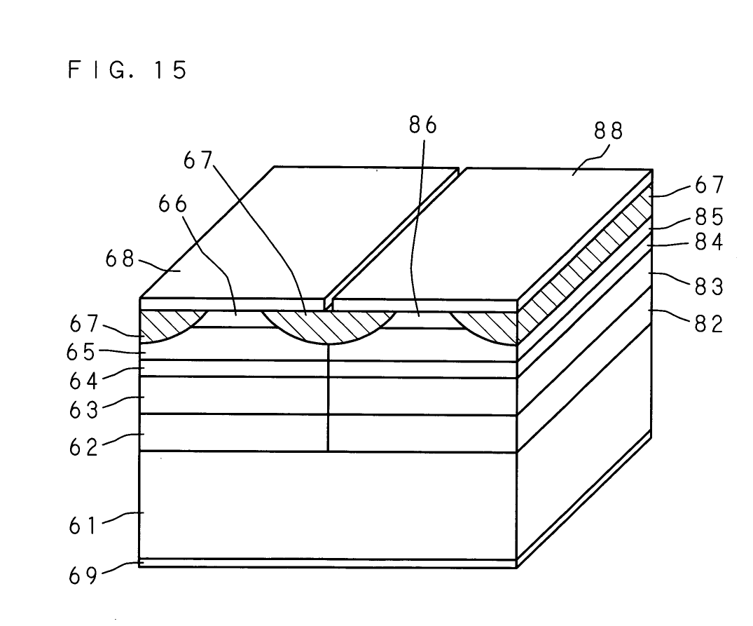

FIG. 14 is a schematic diagram of the structure of a high power-type laser diode chip. In FIG. 14, reference numeral 51 denotes an about 500 Å thick MQW active layer formed by alternately laminating quantum well layers, which are an extremely thin film 100 Å thick or less and which are made of GaInN-based semiconductor crystal, and quantum barrier layers which are an extremely thin film 100 Å thick or less and which are made of GaInN-based semiconductor crystal. A p-type AlGaN waveguide layer 52, which is used to confine light and which is made of p-type AlGaN-based semiconductor crystal, and a n-type AlGaN waveguide layer 50, which is made of n-type AlGaN-based semiconductor crystal, are provided so as to sandwich the MQW active layer 51; that is, the p-type AlGaN waveguide layer 52 overlies the MQW active layer 51 and the n-type AlGaN waveguide layer 50 underlies the MQW active layer 51. Incidentally, the explanation of the same components as those described in the seventh embodiment is omitted instead of giving the same reference numerals.

With the structure of the laser diode chip according to the ninth embodiment, both side portions of the p-type GaN capping layer 46 are removed by etching, upper parts of both side portions of the p-type AlGaN clad layer 45 are removed by etching, and the current restricting layers 47 are provided to the cut portions. The depths of the current restricting layers 47 are increased toward the longitudinal edges of the laser diode chip.

As a result, carriers confined in the MQW active layer 51 come to have a discrete energy level (sublevel) higher than their energy level at an energy band. Since the transition of the carriers occurs between these sublevels, the energy of light emission becomes high and the amplification of the light increases, thereby laser oscillation can be effected with small currents and a high-power laser beam can be outputted.

In the seventh, eighth, and ninth embodiments of the invention in which the laser diode chips which output the violet laser beam with the wavelength on the order of 405 nm are described, the p-type AlGaN clad layer 45 and the n-type AlGaN clad layer 43 each have a single-layer structure; however, their structures are not limited to such a structure and hence, plural p-type AlGaN clad layers and n-type AlGaN clad layers may be provided both of which are made of semiconductor crystal having modified chemical compositions.

### Tenth Embodiment

FIG. 15 is a schematic diagram of the structure of a laser diode chip according to a tenth embodiment of the invention. In FIG. 15, reference numeral 61 denotes a n-type GaAs substrate made of n-type GaAs-based semiconductor crystal. The n-type GaAs substrate 61 is of the shape of, for example, a rectangular parallelepiped approximately 500 μm wide (width)×100 μm thick (height)×400 μm long.

On the substantially half region of the n-type GaAs substrate 61, for example, an about 0.5 μm thick n-type GaAs buffer layer 62 made of n-type GaAs-based semiconductor crystal, an about 0.5 μm thick n-type AlGaAs clad layer 63 made of n-type AlGaAs-based semiconductor crystal, an about 0.06 μm thick AlGaAs active layer 64 made of AlGaAs-based semiconductor crystal, an about 0.5 μm thick p-type AlGaAs clad layer 65 made of p-type AlGaAs-based semiconductor crystal, and an about 0.5 μm thick p-type GaAs capping layer 66 made of p-type GaAs-based semiconductor crystal are laminated in that order by epitaxial crystal growth.

Also, on the remaining substantially half region of the n-type GaAs substrate 61, for example, an about 0.5 μm thick n-type GaInP buffer layer 82 made of n-type GaInP-based semiconductor crystal, an about 0.5 μm thick n-type AlGaInP clad layer 83 made of n-type AlGaInP-based semiconductor crystal, an about 0.06 μm thick GaInP active layer 84 made of GaInP-based semiconductor crystal, an about 0.5 μm thick p-type AlGaInP clad layer 85 made of p-type AlGaInP-based semiconductor crystal, and an about 0.5 μm thick p-type GaAs capping layer 86 made of p-type GaAs-based semiconductor crystals are laminated in that order by epitaxial crystal growth. A lateral separation between the center of the n-type AlGaAs clad layer 63 and the center of the n-type AlGaInP clad layer 83 is, for example, 100 to 120 μm. In FIG. 15, it should be noted that the thicknesses of the individual layers are exaggerated to facilitate the understanding of the structure of the diode laser chip and the thicknesses of the layers other than the n-type GaAs substrate 61 are several μm or less.

Both side portions separated by the central portions (stripes) of the p-type GaAs capping layer 66 and the p-type AlGaAs clad layer 65 and parallel to cleavage planes are cut away by etching. Also, both side portions separated by the central portions of the p-type GaAs capping layer 86 and the p-type AlGaInP clad layer 85 and parallel to the cleavage planes are cut away by etching. The p-type GaAs capping layer 66, the p-type AlGaAs clad layer 65, the p-type GaAs capping layer 86, and the p-type AlGaInP clad layer 85 are of the shape of a mountain in the cleavage plane. Three current restricting layers 67, which are made of an oxide film formed by baking a liquid oxide film, are each provided to the cut portions. Therefore the current restricting layers 67 are provided oppositely one after the other with the central portions of the p-type GaAs capping layer 66 and the p-type AlGaAs clad layer 65 and of the p-type GaAs capping layer 86 and the p-type AlGaInP clad layer 85, which lie vertically to the direction of both laminations, interposed therebetween. That is, by providing the current restricting layers 67 whose refractive index is equal to or lower than those of the n-type AlGaAs clad layer 63 and the n-type AlGaInP clad layer 83, a double heterostructure is formed in the laser diode chip. Two p-type electrodes 68 and 88 are formed on the surfaces of the current restricting layers 67 and the p-type GaAs capping layers 66 and 86. An n-type electrode 69 is formed on the bottom surface of the n-type GaAs substrate 61.

The laser diode chip operates by feeding forward electric currents between the p-type electrode 68 and the n-type electrode 69 and between the p-type electrode 88 and the n-type electrode 69. The current flowing into the AlGaAs active layer 64 via the p-type electrode 68 is restricted by the current restricting layers 67 and is confined in the restricted region (active region) of the AlGaAs active layer 64. The current flowing into the GaInP active layer 84 via the p-type electrode 88 is restricted by the current restricting layers 67 and is confined in the restricted region (active region) of the GaInP active layer 84. Carriers (electrons and holes) injected by the currents concentrate into the active regions and light generated by the coupling of the carriers is confined in the active regions by using the double heterostructure in which the AlGaAs active layer 64 with a high refractive index is sandwiched between the n-type AlGaAs clad layer 63 and the p-type AlGaAs clad layer 65 with low refractive indices and in which the GaInP active layer 84 with a high refractive index is sandwiched between the n-type AlGaInP clad layer 83 and the p-type AlGaInP clad layer 85 with low refractive indices. When the forward currents are increased so as to exceed threshold current, laser oscillation occurs, thereby laser beams with two wavelengths of 780 nm and 650 nm can be taken out of the cleavage plane.

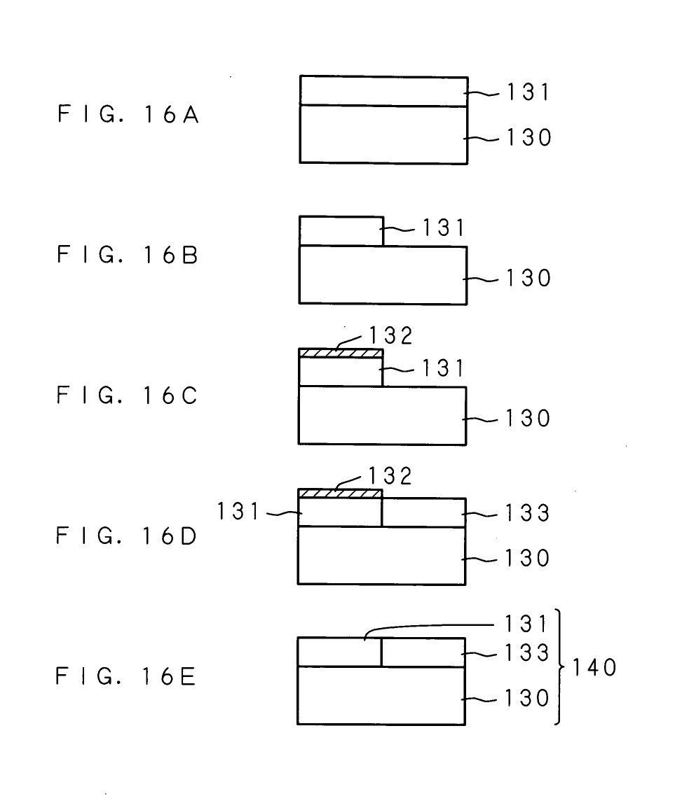

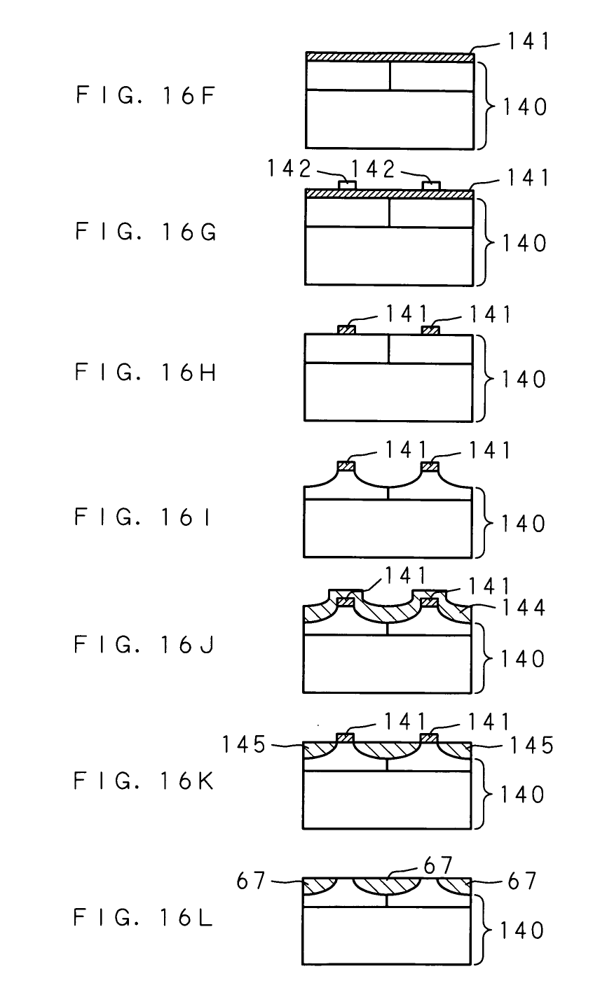

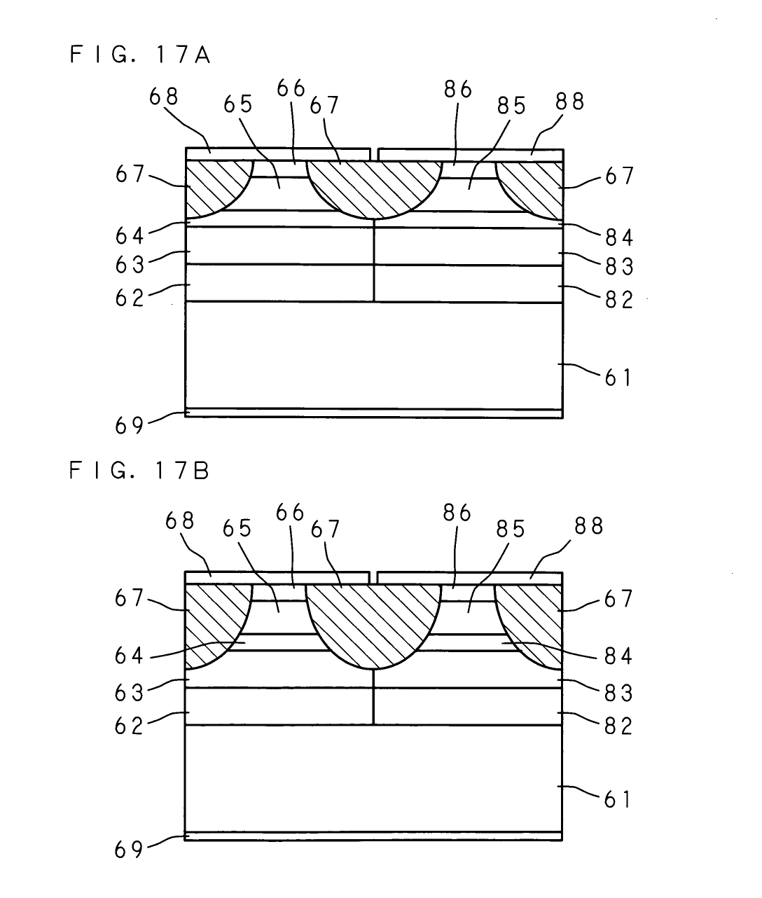

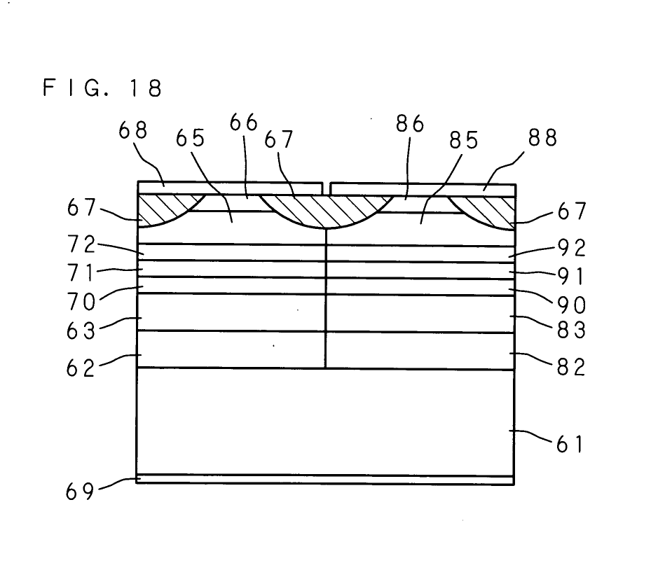

FIGS. 16A to 16L are explanatory drawings of a process for manufacturing the laser diode chip according to the tenth embodiment of the invention having such a structure. A GaAs-based semiconductor layer 131 is formed on a n-type GaAs-based semiconductor substrate 130 by epitaxial crystal growth so as to have a predetermined layer structure (FIG. 16A). Part of the GaAs-based semiconductor layer 131 formed by the crystal growth is removed by etching until the substrate 130 is exposed (FIG. 16B). An insulating film 132 is formed on the surface of the GaAs-based semiconductor layer 131 (FIG. 16C) and an AlGaInP-based/GaInP-based semiconductor layer 133 is formed onto the portion, where the GaAs-based semiconductor layer 131 has been removed by etching, by epitaxial crystal growth so as to have a predetermined layer structure (FIG. 16D). The insulating film 132 is removed (FIG. 16E) to produce a wafer 140 used for the formation of the two different wavelengths.

An insulating film 141 is formed on the growth surface of the wafer 140 by P-CVD (FIG. 16F). A photoresist 142 is applied onto the surface of the insulating film 141, exposure is conducted through the use of a mask, and exposed portions are removed with a chemical solution (FIG. 16G).

The insulating film 141 is removed by dry etching except for unexposed portions (FIG. 16H). And further, both side portions of the individual clad layers and active layers are cut away by etching (FIG. 16I). Incidentally, the portions to be cut away can be cut away in gradually increasing their depths from the central portions to the longitudinal edges. To the wafer 140 having the p-type GaAs capping layer 66, the p-type AlGaAs clad layer 65, the p-type GaAs capping layer 86, and the p-type AlGaInP clad layer 85, all of which are cut away at their both side portions, a liquid oxide film 144 (for example, a coating liquid mainly comprising silicon oxide) is applied so as to have a desired thickness and to cover the insulating films 141, after which the wafer 140 is baked (for example, at temperatures of 80° C., 150° C., and 200° C. for 1 minute each and then baked at a temperature of 400° C. to 500° C. for 30 minutes) (FIG. 16J).

Part of the baked oxide film 145 is removed by etching until the insulating films 141 are exposed, and then the surface of the oxide film 145 is smoothened (FIG. 16K), following which the exposed insulating films 141 are removed by etching (FIG. 16L). As a result, the current restricting layers 67 are formed which are made by baking the liquid oxide film 144 instead of the growth of the semiconductor crystal.

Metal films serving as the p-type electrodes 68 and 88 are formed on the surfaces of the p-type GaAs capping layers 66 and 68. Also, a metal film serving as the n-type electrode 69 is formed on the bottom surface of the substrate 61. The wafer having the metal films is cut into the individual laser diode chips. The two end faces of the chip, which serve as a light resonator, are formed as flat planes (cleavage planes) parallel to each other. And finally, a laser diode is manufactured by mounting the laser diode chip onto a package and bonding a wire used for sending electric current.

As explained above, by providing the current restricting layers, which are made of the liquid oxide film instead of conventional epitaxial crystal growth and which confine the carriers and light, with the central portions (stripes) of the p-type GaAs capping layer and the p-type AlGaAs clad layer and of the p-type GaAs capping layer and the p-type AlGaInP clad layer sandwiched therebetween, the process of the epitaxial crystal growth, which has been required to provide current restricting layers, becomes unnecessary; hence it is possible to improve the yield of the chip, save time and labor required for the manufacturing process thereof, and reduce the production cost thereof. Also, through the physical provision of the current restricting layers to the p-type GaAs capping layers, the p-type AlGaAs clad layer, and the p-type AlGaInP clad layer, there are no disadvantages that the threshold current, by which the laser oscillation is started, becomes large and an astigmatic difference is large.

In the tenth embodiment of the invention, the size of the substrate of the laser diode chip and the thicknesses of the individual semiconductor layers are indicated as examples and hence are not limited to those numeric values. Also, it is needless to say that the proportions of the individual elements included in the AlGaAs-based semiconductor, the GaAs-based semiconductor, the AlGaInP-based semiconductor, and the GaInP-based semiconductor can be set at desired ratios.

### Eleventh Embodiment

With the laser diode chip according to the tenth embodiment of the invention, both side portions of the p-type GaAs capping layers 66 and 86 are removed by etching, upper parts of both side portions of the p-type AlGaAs clad layer 65 and the p-type AlGaInP clad layer 85 are removed by etching, and the current restricting layers are provided to the cut portions; however, the structure of the current restricting layers is not limited to such a structure.

FIGS. 17A and 17B are schematic diagrams of the structures of the current restricting layers 67. As shown in FIG. 17A, both side portions of the p-type GaAs capping layer 66 and the p-type AlGaAs clad layer 65 and of the p-type GaAs capping layer 86 and the p-type AlGaInP clad layer 85 are removed by etching and upper parts of both side portions of the AlGaAs active layer 64 and the GaInP active layer 84 are removed by etching. The depths of the removed portions are increased toward the longitudinal edges of the laser diode chip. The current restricting layers 67 formed by baking a liquid oxide film are provided to the cut portions.

Also, as shown in FIG. 17B, both side portions of the p-type GaAs capping layer 66, the p-type AlGaAs clad layer 65, and AlGaAs active layer 64 and of the p-type GaAs capping layer 86, the p-type AlGaInP clad layer 85, and the GaInP active layer 84 are removed by etching and upper parts of both side portions of the n-type AlGaAs clad layer 63 and the n-type AlGaInP clad layer 83 are removed by etching. The depths of the removed portions are increased toward the longitudinal edges of the laser diode chip. The current restricting layers 67 formed by baking the liquid oxide film are provided to the cut portions. Therefore it is also possible to adopt the double heterostructure in the longitudinal and horizontal directions of the laser diode chip, thereby a higher-efficiency laser diode chip can be manufactured.

### Twelfth Embodiment

The laser diode chips according to the tenth and eleventh embodiments of the invention have such structures, in which the active layer made of the AlGaAs-based semiconductor crystal and the active layer made of the GaInP-based semiconductor crystal are used, and output the laser beams having the infrared and red wavelengths and the laser power on the order of several mW to several tens of mW And further, it is also possible to apply such structures to a laser diode chip which outputs an infrared laser beam with a high power on the order of a hundred mW to several hundred mW.

FIG. 18 is a schematic diagram of the structure of a high power-type laser diode chip. In FIG. 18, reference numeral 71 denotes an about 500 Å thick MQW active layer formed by alternately laminating quantum well layers, which are an extremely thin film 100 Å thick or less and which are made of AlGaAs-based semiconductor crystal, and quantum barrier layers which are an extremely thin film 100 Å thick or less and which are made of GaAs-based semiconductor crystal. A p-type AlGaAs waveguide layer 72, which is used to confine light and which is made of p-type AlGaAs-based semiconductor crystal, and a n-type AlGaAs waveguide layer 70, which is made of n-type AlGaAs-based semiconductor crystal, are provided so as to sandwich the MQW active layer 71; that is the p-type AlGaAs waveguide layer 72 overlies the MQW active layer 71 and the n-type AlGaAs waveguide layer 70 underlies the MQW active layer 71.

Also, reference numeral 91 denotes an about 500 Å thick MQW active layer formed by alternately laminating a quantum well layer, which is an extremely thin film 100 Å thick or less and which is made of AlGaInP-based semiconductor crystal, and a quantum barrier layer which is an extremely thin film 100 Å thick or less and which is made of GaInP-based semiconductor crystal. A p-type AlGaInP waveguide layer 92, which is used to confine light and which is made of p-type AlGaInP-based semiconductor crystal, and a n-type AlGaInP waveguide layer 90, which is made of n-type AlGaInP-based semiconductor crystal, are provided so as to sandwich the MQW active layer 91; that is, the p-type AlGaInP waveguide layer 92 overlies the MQW active layer 91 and the n-type AlGaInP waveguide layer 90 underlies the MQW active layer 91. Incidentally, the explanation of the same constituents as those described in the tenth embodiment is omitted instead of giving the same reference numerals.

With the structure of the laser diode chip according to the twelfth embodiment of the invention, both side portions of the p-type GaAs capping layers 66 and 86 are remove by etching, upper parts of both side portions of the p-type AlGaAs clad layer 65 and the p-type AlGaInP clad layer 85 are removed by etching, and the current restricting layers 67 are provided to the removed portions. The depths of the current restricting layers 67 are increased toward the longitudinal edges of the laser diode chip.

As a result, carriers confined in the MQW active layers 71 and 91 have a discrete energy level (sublevel) higher than their energy level at an energy band. Since the transition of the carriers occurs between these sublevels, the energy of light emission becomes high and the amplification of the light is increased, thereby laser oscillation can be effected with small currents and a high-power laser beam can be outputted.

In the tenth, eleventh, and twelfth embodiment of the invention, the p-type AlGaAs clad layer 65, the n-type AlGaAs clad layer 63, the p-type AlGaInP clad layer 85, and the n-type AlGaInP clad layer 83 have a single-layer structure; however, their structures are not limited to such a structure and hence, plural p-type AlGaAs clad layers, n-type AlGaAs clad layers, p-type AlGaInP clad layers, and n-type AlGaInP clad layers may be provided all of which are made of semiconductor crystals having modified chemical compositions.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1. A laser diode chip comprising:
a substrate;
a first clad layer of a n-type semiconductor laminated on the substrate;
an active layer laminated on the first clad layer;
a second clad layer of a p-type semiconductor laminated on the active layer; and
current restricting layers which are formed by baking a liquid oxide film and which are provided so as to be opposite to each other with a central portion of the second clad layer, which lies substantially vertically to the direction of the lamination, interposed therebetween.

2. The laser diode chip according to claim 1, wherein the thicknesses of the current restricting layers are increased with distance from the central portion.

3. The laser diode chip according to claim 1, wherein the current restricting layers are provided so as to be opposite to each other with a central portion of the first clad layer, which lies substantially vertically to the direction of the lamination, interposed therebetween.

4. The laser diode chip according to claim 1, wherein the active layer is a multiple quantum well layer alternately laminated with quantum well layers and quantum barrier layers.

5. The laser diode chip according to claim 1, wherein the first clad layer is made of a n-type AlGaAs-based semiconductor, the active layer is made of an AlGaAs-based semiconductor, and the second clad layer is made of a p-type AlGaAs-based semiconductor.

6. The laser diode chip according to claim 1, wherein the first clad layer is made of a n-type AlGaInP-based semiconductor, the active layer is made of a GaInP-based semiconductor, and the second clad layer is made of a p-type AlGaInP-based semiconductor.

7. The laser diode chip according to claim 1, wherein the first clad layer is made of a n-type AlGaN-based semiconductor, the active layer is made of a GaInN-based semiconductor, and the second clad layer is made of a p-type AlGaN-based semiconductor.

8. A laser diode comprising the laser diode chip according to claim 1.

9. A laser diode chip comprising:
a substrate;
a first n-type semiconductor clad layer laminated on the substrate;
a first active layer laminated on the first n-type semiconductor clad layer;
a first p-type semiconductor clad layer laminated on the first active layer;
a second n-type semiconductor clad layer laminated on the substrate;
a second active layer laminated on the second n-type semiconductor clad layer;
a second p-type semiconductor clad layer laminated on the second active layer; and
current restricting layers which are formed by baking a liquid oxide film and which are provided oppositely one after the other with individual central portions of the first p-type semiconductor clad layer and the second p-type semiconductor clad layer, which lie substantially vertically to the direction of the lamination, interposed therebetween.

10. The laser diode chip according to claim 9, wherein the thicknesses of the current restricting layers are increased with distance from the individual central portions of the first and second p-type semiconductor clad layers.

11. The laser diode chip according to claim 9, wherein the current restricting layers are provided oppositely one after the other with individual central portions of the first n-type semiconductor clad layer and the second n-type semiconductor clad layer, which lie substantially vertically to the direction of the lamination, interposed therebetween.

12. The laser diode chip according to claim 9, wherein the first and second active layers are multiple quantum well layers alternately laminated with quantum well layers and quantum barrier layers.

13. The laser diode chip according to claim 9, wherein the first n-type semiconductor clad layer, the first active layer, and the first p-type semiconductor clad layer are AlGaAs-based semiconductors, the second n-type semiconductor clad layer and the second p-type semiconductor clad layer are AlGaInP-based semiconductors, and the second active layer is a GaInP-based semiconductor.

14. A laser diode comprising the laser diode chip according to claim 9.

15. A method for manufacturing a laser diode chip, in which at least a first clad layer of a n-type semiconductor, an active layer, and a second clad layer of a p-type semiconductor are laminated on a substrate in that order, comprising steps of
forming an insulating film so as to cover a central portion of the second clad layer which lies substantially vertically to the direction of the lamination;
removing part of the second clad layer, which is not covered with the insulating film, by etching;
applying a liquid oxide film onto the semiconductor layer and the insulating film which are exposed by the etching;
baking the applied liquid oxide film;
smoothening the baked oxide film by etching until the insulating film is exposed; and
removing the exposed insulating film by etching.

16. The method for manufacturing the laser diode chip according to claim 15, wherein the first clad layer is made of a n-type AlGaAs-based semiconductor, the active layer is made of an AlGaAs-based semiconductor, and the second clad layer is made of a p-type AlGaAs-based semiconductor.

17. The method for manufacturing the laser diode chip according to claim 15, wherein the first clad layer is made of a n-type AlGaInP-based semiconductor, the active layer is made of a GaInP-based semiconductor, and the second clad layer is made of a p-type AlGaInP-based semiconductor.

18. The method for manufacturing the laser diode chip according to claim 15, wherein the first clad layer is made of a n-type AlGaN-based semiconductor, the active layer is made of a GaInN-based semiconductor, and the second clad layer is made of a p-type AlGaN-based semiconductor.

19. A method for manufacturing a laser diode chip, in which at least a first n-type semiconductor clad layer, a first active layer, and a first p-type semiconductor clad layer are laminated on a substrate in that order, and at least a second n-type semiconductor clad layer, a second active layer, and a second p-type semiconductor clad layer are laminated on the substrate in that order and which outputs laser beams with different wavelengths, comprising steps of
forming insulating films so as to cover individual central portions of the first and second p-type semiconductor clad layers which lie substantially vertically to the directions of the laminations;
removing parts of the first and second p-type semiconductor clad layers which are not covered with the insulating films by etching;
applying a liquid oxide film onto the semiconductor layers and the insulating films exposed by the etching;
baking the applied liquid oxide film;
smoothening the baked oxide film by etching until the insulating films are exposed; and
removing the exposed insulating films by etching.

20. The method for manufacturing the laser diode chip according to claim 19, wherein the first n-type semiconductor clad layer, the first active layer, and the first p-type semiconductor clad layer are AlGaAs-based semiconductors, the second n-type semiconductor clad layer and the second p-type semiconductor clad layer are AlGaInP-based semiconductors, and the second active layer is a GaInP-based semiconductor.
